(19) United States
(12) Patent Application Publication
(10) Pub. No.: US 2026/0323975 A1
(43) Pub. Date: Oct. 15, 2026

(54) SEMICONDUCTOR DEVICE

(71) Applicant: ROHM CO., LTD., Kyoto-shi (JP)

(72) Inventors: Takuya MATSUMOTO, Kyoto-shi (JP); Yuma ISHISAKA, Kyoto-shi (JP); Nobutaka OI, Kyoto-shi (JP)

(73) Assignee: ROHM CO., LTD., Kyoto-shi (JP)

(21) Appl. No.: 19/687,121

(22) Filed: May 26, 2026

Related U.S. Application Data
(63) Continuation of application No. PCT/JP2024/038668, filed on Oct. 30, 2024.

(30) Foreign Application Priority Data
Dec. 5, 2023 (JP) 2023-205254

(51) Int. Cl. H10D 12/00; H10D 62/10; H10D 62/17; H10D 64/00; H10D 64/23

(52) U.S. Cl. CPC H10D 12/481; H10D 62/127; H10D 62/393; H10D 64/117; H10D 64/232

(57) ABSTRACT

A semiconductor device includes a semiconductor layer, first and second trenches extending into the semiconductor layer, an insulating layer on the semiconductor layer, a first electrode in the first trench, and a second electrode in the second trench. The second electrode is electrically insulated from the first electrode. Contact plugs extend through the insulating layer and contact the semiconductor layer. The first and second trenches extend in a first direction. The first trench is separated from the second trench in a second direction orthogonal to the first direction. The semiconductor layer includes a mesa between the first trench and the second trench. The contact plugs include a contact plug row in contact with the mesa. The contact plug row overlaps the second trench in plan view and is separated from the first trench. The contact plugs in the row are spaced apart in the first direction.

### CROSS-REFERENCE TO RELATED APPLICATIONS

This application is a continuation of, and claims the benefit of priority from International Application No. PCT/JP2024/038668, filed on Oct. 30, 2024, which claims the benefit of priority from Japanese Patent Application No. 2023-205254, filed on Dec. 5, 2023, the entire contents of each of which are incorporated herein by reference.

### BACKGROUND

### 1. Field

The present disclosure relates to a semiconductor device.

### 2. Description of Related Art

WO2020/080476A discloses a semiconductor device including an insulated-gate bipolar transistor (IGBT) having a trench gate structure. The IGBT includes an emitter plug electrode electrically connected to an emitter region and to a contact region. The emitter plug electrode is embedded in an emitter trench.

Other features and aspects will be apparent from the following detailed description, the drawings, and the claims.

### BRIEF DESCRIPTION OF THE DRAWINGS

FIG. 1 is a schematic plan view of an exemplary semiconductor device in accordance with a first embodiment of the present disclosure.

FIG. 2 is a schematic perspective view showing a portion of an active region in the semiconductor device of FIG. 1.

FIG. 3 is a schematic plan view showing the portion encompassed by single-dashed line F3 in the semiconductor device of FIG. 1.

FIG. 4 is a schematic cross-sectional view of the semiconductor device taken along line F4-F4 in FIG. 3.

FIG. 5 is a schematic cross-sectional view of the semiconductor device taken along line F5-F5 in FIG. 3.

FIG. 6 is an enlarged view of a portion shown in FIG. 4.

FIG. 7 is a schematic cross-sectional view of the semiconductor device taken along line F7-F7 in FIG. 3.

FIG. 8 is a schematic plan view showing the portion encompassed by single-dashed line F8 in the semiconductor device of FIG. 1.

FIG. 9 is a schematic cross-sectional view of the semiconductor device taken along line F9-F9 in FIG. 8.

FIG. 10 is a schematic plan view of a semiconductor device in a further example of the present disclosure.

FIG. 11 is a schematic cross-sectional view of the semiconductor device taken along line F11-F11 in FIG. 10.

FIG. 12 is a schematic cross-sectional view of the semiconductor device taken along line F12-F12 in FIG. 10.

FIG. 13 is an enlarged view of a portion shown in FIG. 11.

FIG. 14 is a schematic plan view of a semiconductor device in a further example of the present disclosure.

FIG. 15 is a schematic cross-sectional view of the semiconductor device taken along line F15-F15 in FIG. 14.

FIG. 16 is an enlarged view of a portion shown in FIG. 15.

FIG. 17 is a schematic cross-sectional view of a semiconductor device in a further example of the present disclosure.

FIG. 18 is a schematic cross-sectional view of the semiconductor device taken from a different direction from that of FIG. 17.

FIG. 19 is a schematic plan view of an exemplary semiconductor device in accordance with a second embodiment of the present disclosure.

FIG. 20 is a schematic cross-sectional view of the semiconductor device shown in FIG. 19.

FIG. 21 is a schematic cross-sectional view of the semiconductor device shown in FIG. 19.

FIG. 22 is an enlarged plan view of the semiconductor device showing a state in which contact plugs are misaligned in the X-direction.

FIG. 23 is a schematic cross-sectional view of the semiconductor device shown in FIG. 22.

FIG. 24 is an enlarged plan view of a semiconductor device lacking complementary regions, showing a state in which the contact plugs are misaligned in the X-direction.

FIG. 25 is a schematic cross-sectional view of the semiconductor device shown in FIG. 24.

FIG. 26 is a schematic plan view of a semiconductor device in a further example of the present disclosure.

FIG. 27 is a schematic plan view of a semiconductor device in a further example of the present disclosure.

FIG. 28 is a schematic cross-sectional view of a semiconductor device in a further example of the present disclosure.

FIG. 29 is a schematic plan view of an exemplary semiconductor device in accordance with a third embodiment.

FIG. 30 is a schematic cross-sectional view of the semiconductor device taken along line F30-F30 in FIG. 29.

FIG. 31 is a schematic cross-sectional view of the semiconductor device taken along line F31-F31 in FIG. 29.

FIG. 32 is a schematic cross-sectional view of the semiconductor device showing a state in which contact plugs are misaligned in the X-direction.

FIG. 33 is a schematic cross-sectional view of a semiconductor device including a first electrode lacking recesses, showing a state in which the contact plugs are misaligned in the X-direction.

FIG. 34 is a schematic plan view of a semiconductor device in a further example of the present disclosure.

FIG. 35 is a schematic cross-sectional view of the semiconductor device taken along line F35-F35 in FIG. 34.

FIG. 36 is a schematic plan view of a semiconductor device in a further example of the present disclosure.

FIG. 37 is a schematic cross-sectional view of the semiconductor device taken along line F37-F37 in FIG. 36.

### DETAILED DESCRIPTION

Several embodiments of a semiconductor device in accordance with the present disclosure will now be described with reference to the accompanying drawings. Throughout the drawings and the detailed description, the same reference characters denote the same elements. The drawings may not be to scale, and the relative size, proportions, and depiction of elements in the drawings may be exaggerated for clarity, illustration, and convenience.

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

### First Embodiment

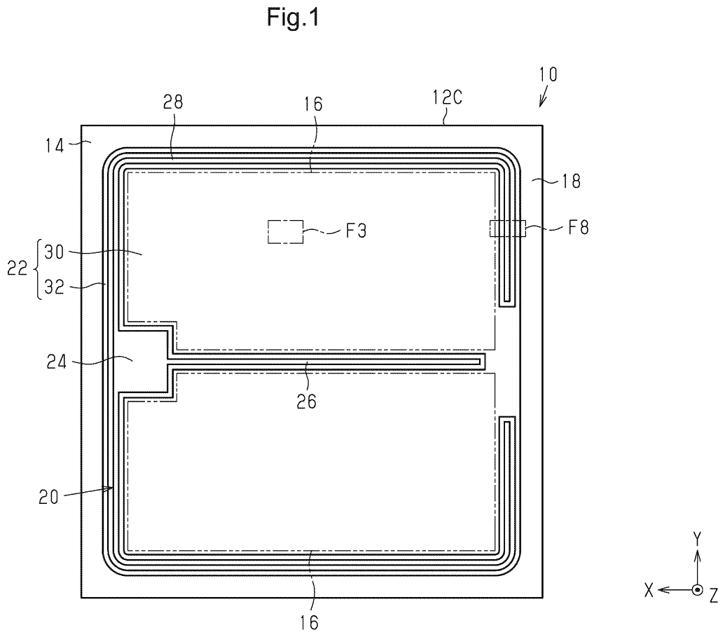

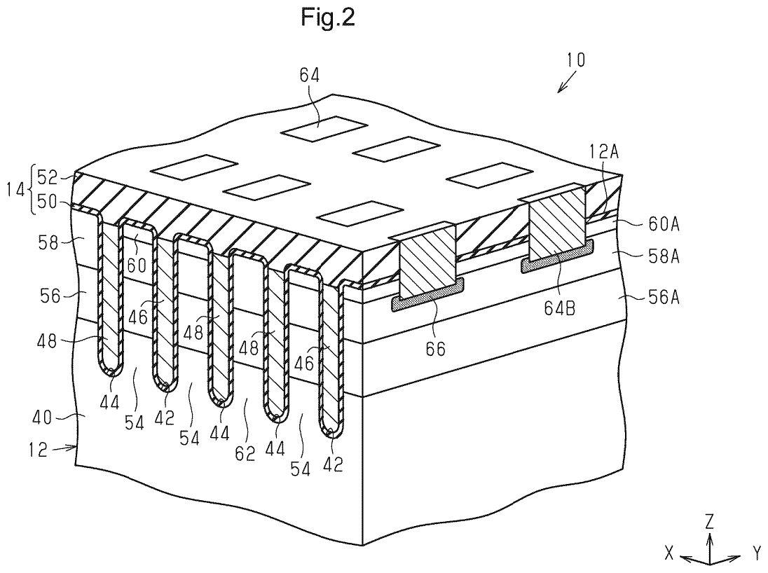

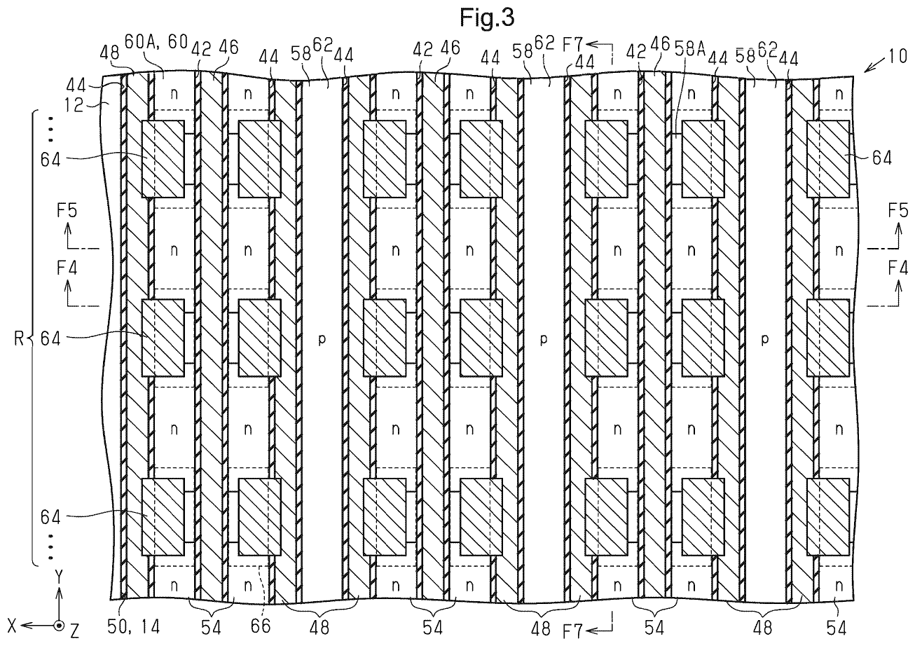

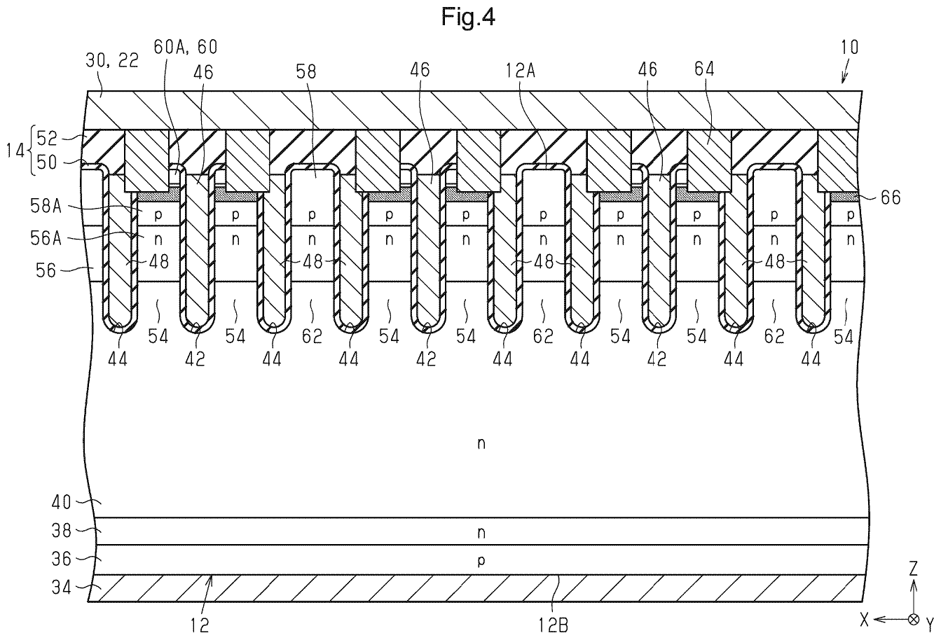

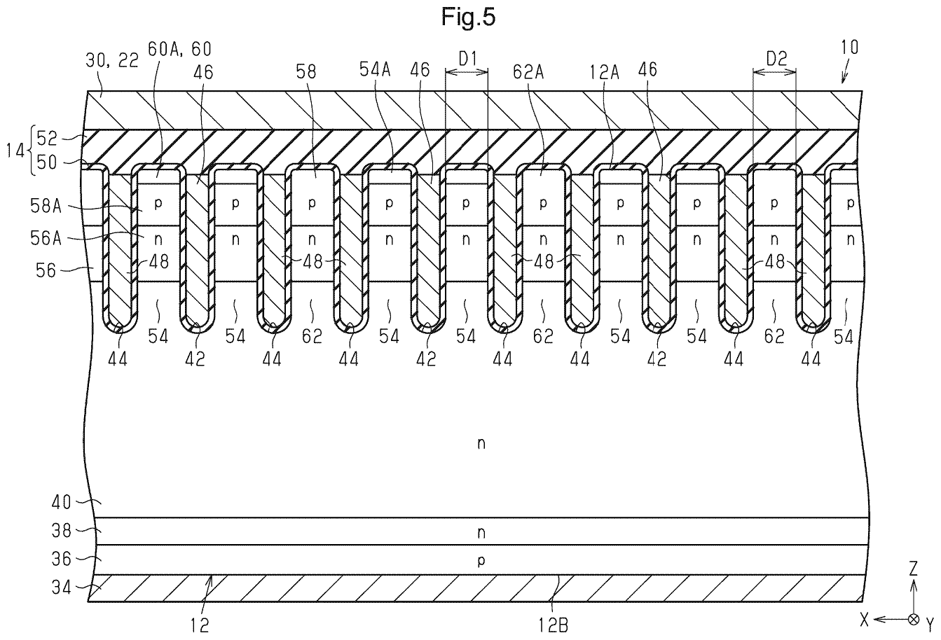

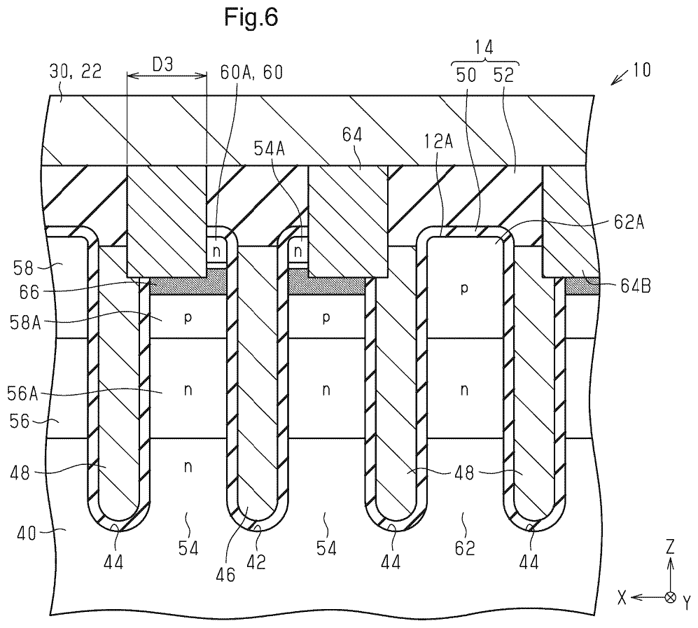

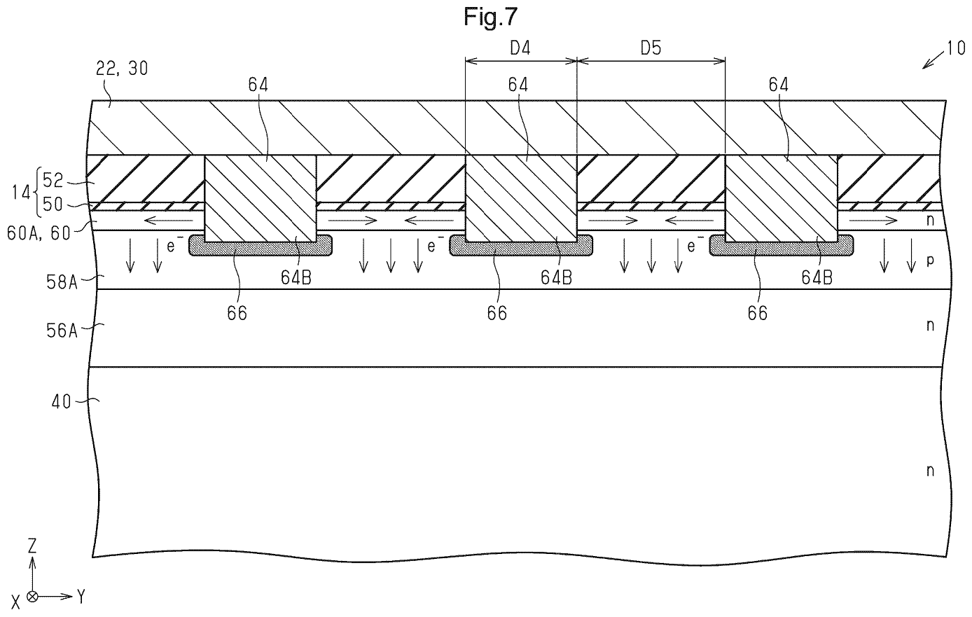

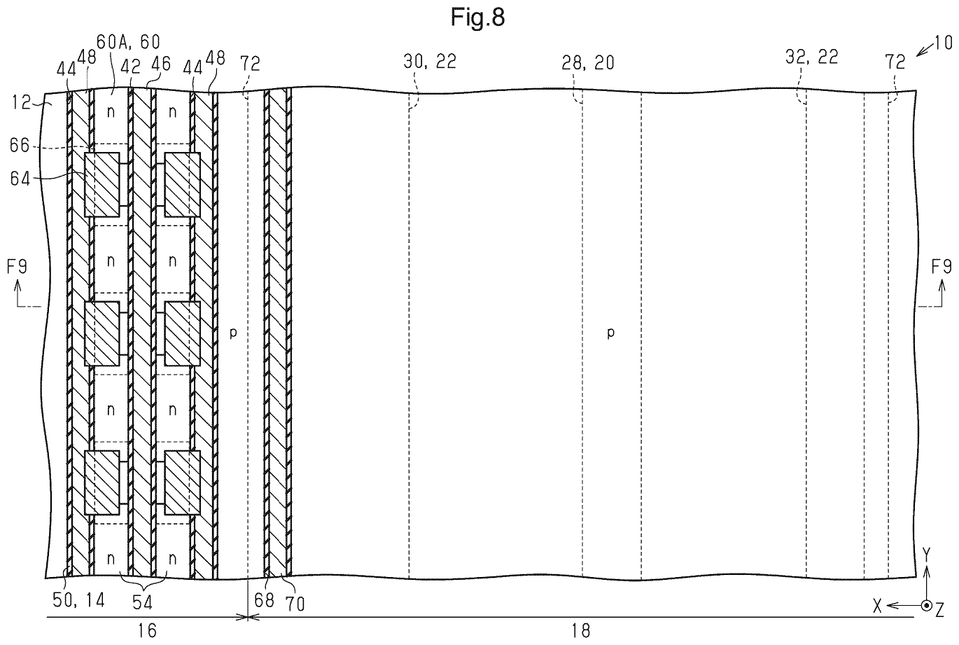

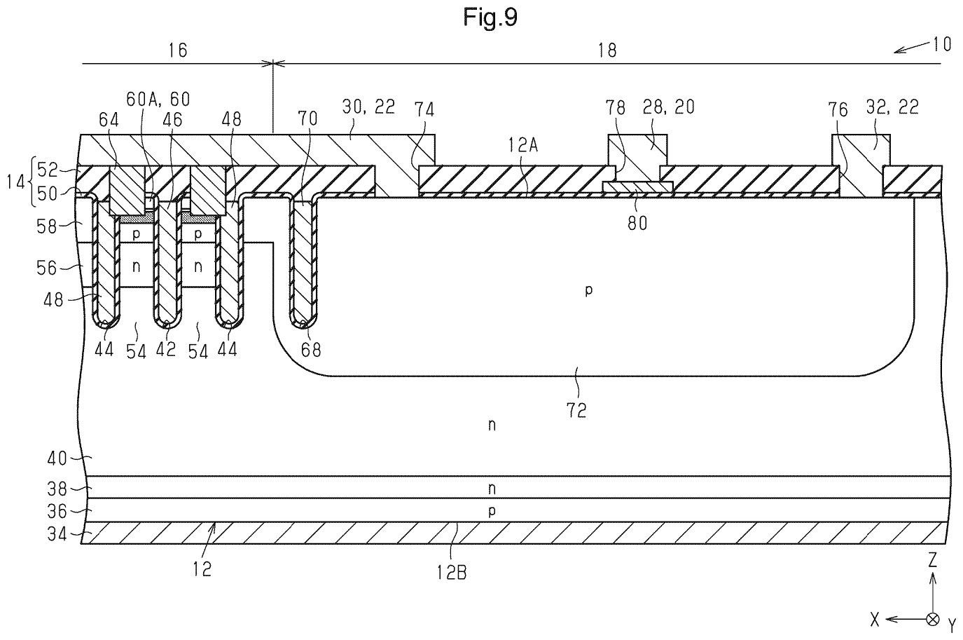

With reference to FIGS. 1 to 9, an exemplary semiconductor device 10 in accordance with a first embodiment will now be described. The semiconductor device 10 may be a semiconductor chip including an insulated-gate bipolar transistor (IGBT). FIG. 1 is a schematic plan view of an exemplary semiconductor device 10 in accordance with one embodiment. FIG. 2 is a schematic perspective view showing a portion of an active region 16 in the semiconductor device 10 of FIG. 1. FIG. 2 does not show an emitter electrode 22 to facilitate understanding of the arrangement of contact plugs 64. FIG. 3 is a schematic plan view showing the portion encompassed by single-dashed line F3 in the semiconductor device 10 of FIG. 1. FIG. 3 corresponds to a cross-sectional view of the semiconductor device 10 taken along an XY plane intersecting the bottom portions 64B of the contact plugs 64. FIG. 4 is a schematic cross-sectional view of the semiconductor device 10 taken along line F4-F4 in FIG. 3. FIG. 5 is a schematic cross-sectional view of the semiconductor device 10 taken along line F5-F5 in FIG. 3. FIG. 6 is an enlarged view of a portion shown in FIG. 4. FIG. 7 is a schematic cross-sectional view of the semiconductor device 10 taken along line F7-F7 in FIG. 3. FIG. 8 is a schematic plan view showing the portion encompassed by single-dashed line F8 in the semiconductor device 10 of FIG. 1. FIG. 9 is a schematic cross-sectional view of the semiconductor device 10 taken along line F9-F9 in FIG. 8.

FIGS. 1 to 9 indicate X, Y, and Z axes that are orthogonal to one another. The Z-axis direction is orthogonal to a first surface 12A of a semiconductor layer 12 (refer to, for example, FIGS. 2 and 4). Unless otherwise indicated, the term “plan view” as used in this specification will refer to a view of the semiconductor device 10 taken from above in the Z-axis direction (i.e., from the first surface 12A of the semiconductor layer 12). In the present disclosure, the Y-axis direction is also referred to as a first direction, and the X-axis direction is also referred to as a second direction.

As shown in FIGS. 1 to 9, the semiconductor device 10 includes the semiconductor layer 12 and an insulating layer 14 located on the semiconductor layer 12. The semiconductor layer 12 includes the first surface 12A and a second surface 12B opposite the first surface 12A (refer to, for example, FIGS. 4 and 5). The insulating layer 14 may cover the first surface 12A of the semiconductor layer 12. The semiconductor layer 12 may have four edges 12C in plan view (refer to FIG. 1).

The semiconductor layer 12 may include silicon (Si). In an example, the semiconductor layer 12 may be formed substantially from silicon. The insulating layer 14 may include at least one of silicon oxide (SiO₂), silicon nitride (SiN), silicon oxynitride (SiON), and aluminum oxide (Al₂O₃). The insulating layer 14 may be formed by a single insulating layer or by different insulating layers.

As shown in FIG. 1, the semiconductor device 10 may include the active region 16, in which the IGBT is formed, and a peripheral region 18 extending along the edges 12C of the semiconductor layer 12. The peripheral region 18 surrounds the active region 16 in plan view. In the illustrated example, the semiconductor device 10 includes two active regions 16. The layout of the active regions 16 and the peripheral region 18 is not limited to the illustrated example and may be determined in accordance with the desired characteristics of the semiconductor device 10.

The semiconductor device 10 may include a gate electrode 20, which is located on the insulating layer 14, and the emitter electrode 22, which is located on the insulating layer 14. The gate electrode 20 is separated from the emitter electrode 22. The emitter electrode 22 may cover at least the active region 16. In the illustrated example, the gate electrode 20 includes a gate pad 24, an inner gate finger 26, and a peripheral gate finger 28. The inner gate finger 26 is connected to the gate pad 24 and extends between the two active regions 16 in the X-axis direction. The peripheral gate finger 28 is connected to the gate pad 24 and located in the peripheral region 18. Each active region 16 may be at least partially surrounded by the inner gate finger 26 and the peripheral gate finger 28 in plan view. In the illustrated example, the emitter electrode 22 includes an emitter pad 30 and an emitter finger 32. The emitter pad 30 may cover each active region 16. The emitter finger 32 may be connected to the emitter pad 30 and be located in the peripheral region 18. At least a part of the emitter finger 32 may surround the peripheral gate finger 28 in plan view. The peripheral gate finger 28 may be located between the emitter pad 30 and the emitter finger 32. The layout of the gate electrode 20 and the emitter electrode 22 may be determined in accordance with the desired characteristics of the semiconductor device 10 and is not limited to the illustrated example.

The gate electrode 20 may include at least one of aluminum (Al), copper (Cu), an aluminum alloy, a copper alloy, tungsten (W), molybdenum (Mo), nickel (Ni), titanium (Ti), titanium nitride (TiN), tantalum (Ta), and tantalum nitride (TaN). The gate electrode may be formed by a single metal layer or by different metal layers.

The emitter electrode 22 may include at least one of aluminum, copper, an aluminum alloy, a copper alloy, tungsten, molybdenum, nickel, titanium, titanium nitride, tantalum, and tantalum nitride. The emitter electrode 22 may be formed by a single metal layer or by different metal layers.

It is to be understood that the layout of the semiconductor device 10 shown in FIG. 1 is an example, and a different layout may be employed in accordance with desired characteristics of the semiconductor device 10. For example, the location and size of the active region 16 may differ from those shown in the example of FIG. 1. Further, the semiconductor device 10 may include an element other than an IGBT.

As shown in FIGS. 4, 5, and 9, the semiconductor device 10 may include a collector electrode 34 formed on the second surface 12B of the semiconductor layer 12. The collector electrode 34 may include at least one of titanium, nickel, palladium (Pd), gold (Au), silver (Ag), and aluminum. The collector electrode 34 may be formed by a single metal layer or by different metal layers.

The semiconductor layer 12 may include a p-type collector region 36 adjacent to the collector electrode 34. The collector region 36 may include at least a part of the second surface 12B of the semiconductor layer 12. The collector electrode 34 is in ohmic contact with the collector region 36. In an example, the collector region 36 may have a p-type impurity concentration of 1×10¹⁵ cm⁻³ to 1×10¹⁸ cm⁻³, inclusive.

The semiconductor layer 12 may include an n-type buffer region 38, which is located on the collector region 36, and an n-type drift region 40, which is located on the buffer region 38. The drift region 40 has a lower n-type impurity concentration than the buffer region 38. In an example, the buffer region 38 may have an n-type impurity concentration of 1×10¹⁵ cm⁻³ to 1×10¹⁷ cm⁻³, inclusive. In an example, the drift region 40 may have an n-type impurity concentration of 1×10¹³ cm⁻³ to 1×10¹⁵ cm⁻³, inclusive.

In the present disclosure, n-type is also referred to as a first conductivity type, and p-type is also referred to as a second conductivity type. The n-type impurities may be, for example, phosphorus (P) or arsenic (As). The p-type impurities may be, for example, boron (B) or aluminum (Al).

### The Active Region

As shown in FIGS. 2 to 7, the semiconductor device 10 includes gate trenches 42 and dummy trenches 44 extending from the first surface 12A into the semiconductor layer 12. Each gate trench 42 and each dummy trench 44 extends in the Y-axis direction in plan view. The gate trenches 42 are separated from the dummy trenches 44 in the X-axis direction in plan view. In the present disclosure, each gate trench is also referred to as a first trench and each dummy trench is also referred to as a second trench.

The semiconductor device 10 includes a first electrode 46, which is located in each gate trench 42 and separated from the semiconductor layer 12 by the insulating layer 14, and a second electrode 48, which is located in each dummy trench 44 and separated from the semiconductor layer 12 by the insulating layer 14. The second electrode 48 is electrically insulated from the first electrode 46.

Among the trenches 42 and 44 formed in the semiconductor layer 12, the gate trenches 42 are those in which the first electrodes 46 are embedded. The first electrodes 46 may be electrically connected to the gate electrode 20 (refer to FIG. 1).

The first electrodes 46 may be formed from polysilicon, which is conductive. In another example, the first electrodes 46 may be formed from any other conductive material.

Among the trenches formed in the semiconductor layer 12, the dummy trenches 44 are those in which the second electrodes 48 are embedded. The second electrodes 48 may be electrically connected to the emitter electrode 22.

The second electrodes 48 may be formed from polysilicon, which is conductive. In another example, the second electrodes 48 may be formed from any other conductive material.

The insulating layer 14 may include a first insulating layer 50 and a second insulating layer 52 located on the first insulating layer 50. The first insulating layer 50 may cover the first surface 12A of the semiconductor layer 12 and the trenches 42 and 44. The first electrodes 46 and the second electrodes 48 may be embedded in the corresponding gate trenches 42 and dummy trenches 44 with the first insulating layer 50 arranged in between. The second insulating layer 52 covers the first electrodes 46, which are embedded in the gate trenches 42, and the second electrodes 48, which are embedded in the dummy trenches 44.

In an example, the trenches 42 and 44 may each have a depth (dimension in the Z-axis direction) of 1 μm to 30 μm, inclusive. In an example, the trenches 42 and 44 may each have a width (dimension in the X-axis direction) of 0.1 μm to 1 μm, inclusive. In the illustrated example, the trenches 42 and 44 each have side walls extending in the Z-axis direction. In another example, the side walls are inclined with respect to the Z-axis direction.

In the example shown in FIG. 3, the ratio of the number of the gate trenches 42 to the number of the dummy trenches 44 is 1:2. Thus, a set of one gate trench 42 and two dummy trenches 44 is repeatedly arranged in the X-axis direction. The ratio of the number of the gate trenches 42 to the number of the dummy trenches 44 may be determined in accordance with the desired characteristics of the semiconductor device 10 and is not limited to the illustrated example.

In the present embodiment, a pitch of the gate trenches 42 and the dummy trenches 44 in the X-axis direction may be constant. The trenches 42 and 44 may each have the same dimension in the X-axis direction. In another example, the pitch of the trenches 42 and 44 in the X-axis direction does not have to be constant, and the trenches 42 and 44 may have different dimensions in the X-axis direction.

### The Mesa

As shown in FIGS. 3 to 6, the gate trenches 42 are separated from the dummy trenches 44 in the X-axis direction in plan view. The semiconductor layer 12 includes a gate-to-dummy mesa 54 defined between a gate trench 42 and a dummy trench 44. Since the semiconductor device 10 includes a plurality of gate trenches 42 and a plurality of dummy trenches 44, the semiconductor layer 12 may include a plurality of gate-to-dummy mesas 54. In the present disclosure, the gate-to-dummy mesa is also simply referred to as a mesa.

As shown in FIGS. 4 to 6, each gate-to-dummy mesa 54 may include an n-type first region 56A, a p-type second region 58A located on the first region 56A, and an n-type third region 60A located on the second region 58A and including a portion of the first surface 12A of the semiconductor layer 12. Accordingly, at least part of the surface portion of the gate-to-dummy mesa 54 may be the third region 60A.

The first region 56A corresponds to a part of a carrier storage region 56 located on the drift region 40. The carrier storage region 56 may have a greater n-type impurity concentration than the drift region 40. In an example, the carrier storage region 56 may have an n-type impurity concentration of 1×10¹⁵ cm⁻³ to 1×10¹⁷ cm⁻³, inclusive.

The second region 58A corresponds to a part of a base region 58 located on the carrier storage region 56. In an example, the base region 58 may have a p-type impurity concentration of 1×10¹⁵ cm⁻³ to 1×10¹⁸ cm⁻³, inclusive.

The third region 60A corresponds to a part of an emitter region 60 located on the base region 58. The emitter region 60 includes a portion of the first surface 12A of the semiconductor layer 12. In an example, the emitter region 60 may have an n-type impurity concentration of 1×10¹⁹ cm⁻³ to 1×10²⁰ cm⁻³, inclusive.

The gate trenches 42 and the dummy trenches 44 may each have a bottom portion adjacent to the drift region 40. Accordingly, each gate-to-dummy mesa 54 may include a part of the drift region 40.

As shown in FIG. 3, a part of the surface of each gate-to-dummy mesa 54 may be included in the second region 58A. More specifically, a part of the region of each gate-to-dummy mesa 54 adjacent to the corresponding contact plug 64 may be the second region 58A.

In an example, an upper portion 54A of each gate-to-dummy mesa 54 may have dimension D1 in the X-axis direction (refer to FIG. 5) of less than or equal to 1 μm. More preferably, dimension D1 may be less than or equal to 0.8 μm. The upper portion 54A of the gate-to-dummy mesa 54 may include a portion of the first surface 12A of the semiconductor layer 12. If the trenches 42 and 44 each have side walls that are inclined with respect to the Z-axis direction, the upper portion 54A of the gate-to-dummy mesa 54 may be a relatively narrow portion.

In the example shown in FIGS. 2 to 6, the semiconductor layer 12 may further include a dummy-to-dummy mesa 62 defined between two dummy trenches 44 separated from each other in the X-axis direction in plan view. The dummy-to-dummy mesa 62 differs from the gate-to-dummy mesa 54 in that it does not have to be included in the emitter region 60. Accordingly, the surface portion of each dummy-to-dummy mesa 62 may be the base region 58. In other words, in each dummy-to-dummy mesa 62, the base region 58 may include a portion of the first surface 12A of the semiconductor layer 12.

An upper portion 62A of each dummy-to-dummy mesa 62 may have a dimension D2 in the X-axis direction (refer to FIG. 5) that is equal to or different from a width of each gate-to-dummy mesa 54. In an example, dimension D2 is less than or equal to 1 μm. More preferably, dimension D2 may be less than or equal to 0.8 μm.

### The Contact Plugs and the In-Base Regions

As shown in FIGS. 2 to 4, the semiconductor device 10 includes the plurality of contact plugs 64 that extend through the insulating layer 14 and contact the semiconductor layer 12. The plurality of contact plugs 64 include a contact plug row R in contact with the gate-to-dummy mesa 54. Each contact plug 64 included in the row R may extend through the third region 60A of the gate-to-dummy mesa 54. The contact plug row R may be separated from the dummy-to-dummy mesa 62.

The plurality of contact plugs 64 may include a plurality of rows R. In the illustrated example, a single row R may be provided for each gate-to-dummy mesa 54. This means that the contact plugs 64 shown in FIG. 4 are included in different rows R.

As shown in the drawings, each gate trench 42 is located between two of the gate-to-dummy mesas 54. Each gate-to-dummy mesa 54 is in contact with one of the contact plug rows R. Therefore, the gate trench 42 is located between two of the rows R.

The two gate-to-dummy mesas 54, in which the gate trench 42 is located in between, are also respectively referred to as a first mesa and a second mesa. Further, the two rows R may also be referred to as a first contact plug row and a second contact plug row. If the first mesa is defined between the first trench and the second trench and the second mesa is defined between the first trench and a third trench, the first trench corresponds to the gate trench 42. Further, the second trench and the third trench correspond to the dummy trenches 44. Since the third trench corresponds to the dummy trench 44, a third electrode located in the third trench is electrically connected to a second electrode located in the second trench (second electrode 48 located in dummy trench 44). The second contact plug row at least partially overlaps the third trench in plan view and is separated from the first trench.

As shown in FIG. 3, the contact plug rows R at least partially overlap the dummy trenches 44 in plan view and are separated from the gate trenches 42. As shown in FIG. 4, the contact plugs 64 each have a bottom surface located below the upper surface of each second electrode 48. The contact plugs 64 in each row R may be in contact with the corresponding second electrodes 48.

Dimension D1 of the upper portion 54A of each gate-to-dummy mesa 54 (refer to FIG. 5) may be greater than, equal to, or less than dimension D3 of each contact plug 64 in the X-axis direction (refer to FIG. 6). The contact plug rows R at least partially overlap the dummy trenches 44 in plan view. Therefore, dimension D1 of the upper portion 54A of each gate-to-dummy mesa 54 does not necessarily have to be greater than dimension D3 of each contact plug 64. For example, when dimension D1 of the upper portion 54A of each gate-to-dummy mesa 54 is allowed to be less than or equal to dimension D3 of each contact plug 64, the gate-to-dummy mesas 54 can be reduced in size.

The contact plugs 64 in each row R are spaced apart from one another in the Y-axis direction. In an example, the contact plugs 64 in each row R are arranged at constant intervals in the Y-direction. In an example, each contact plug 64 has dimension D4 in the Y-axis direction (refer to FIG. 7) that may be 1 μm to 10 μm, inclusive. Further, interval D5 between the contact plugs 64 in the Y-axis direction may be 1 μm to 10 μm, inclusive. In an example, interval D5 may be greater than dimension D1 of the upper portion 54A of each gate-to-dummy mesa 54 in the X-axis direction. The ratio of dimension D4 and interval D5 may be determined in accordance with the desired characteristics of the semiconductor device 10.

The contact plugs 64 may include at least one of tungsten (W), molybdenum (Mo), nickel (Ni), aluminum (Al), copper (Cu), an aluminum alloy, a copper alloy, titanium (Ti), titanium nitride (TiN), tantalum (Ta), and tantalum nitride (TaN). The contact plugs 64 may be formed by a single metal layer or by different metal layers.

As shown in FIGS. 2, 3, and 7, the gate-to-dummy mesa 54 includes a plurality of p-type in-base regions 66. Each of the plurality of in-base regions 66 is in contact with the bottom portion 64B of a corresponding contact plug 64 in the row R. The plurality of in-base regions 66 are spaced apart from one another in the Y-axis direction.

The in-base regions 66 have a greater p-type impurity concentration than the second region 58A. The p-type impurity concentration of the in-base regions 66 may be 1×10¹⁹ cm⁻³ to 1×10²⁰ cm⁻³, inclusive.

As shown in FIGS. 2, 4, 6, and 7, each in-base region 66 is located between the third region 60A and the first region 56A. Each in-base region 66 is adjacent to the second region 58A. Each in-base region 66 is located in the second region 58A (base region 58). Each in-base region 66 may be located in the second region 58A closer to the third region 60A than to the first region 56A. In the illustrated example, each in-base region 66 may be separated from the third region 60A.

As shown in FIGS. 4, 6, and 7, each of the plurality of in-base regions 66 may extend along the bottom portion 64B of the corresponding contact plug 64 in the gate-to-dummy mesa 54 so as to cover the bottom portion 64B of the contact plug 64. As shown in FIGS. 3, 4, and 6, each in-base region 66 extends across the entire width of the gate-to-dummy mesa 54 in the X-axis direction.

As shown in FIGS. 3 and 7, each in-base region 66 may extend around the bottom portion 64B of the corresponding contact plug 64 in the gate-to-dummy mesa 54. Accordingly, the in-base regions 66 need not be present at a location relatively far from the contact plugs 64, as shown in FIG. 5.

### The Peripheral Region

As shown in FIGS. 8 and 9, in the peripheral region 18, the semiconductor device 10 may include an isolation trench 68, which is formed in the semiconductor layer 12, and an isolation electrode 70, which is embedded in the isolation trench 68 with the first insulating layer 50 located in between. The isolation electrode 70 may be formed from polysilicon, which is conductive. In another example, the isolation electrode 70 may be formed from any other conductive material. The isolation electrode 70 may be electrically connected to the gate electrode 20. Although not shown in the drawings, the isolation trench 68 may be connected to the gate trenches 42 (for example, Y-axis direction ends of the gate trenches 42).

The semiconductor layer 12 may include a p-type peripheral well region 72 in the peripheral region 18. The peripheral well region 72 may surround the active regions 16 in plan view. The peripheral well region 72 may have a greater p-type impurity concentration than the base region 58.

As shown in FIG. 9, the peripheral well region 72 may include a portion of the first surface 12A of the semiconductor layer 12 in the peripheral region 18. The peripheral well region 72 may have a greater depth (Z-axis direction dimension) from the first surface 12A than the isolation trench 68. The isolation trench 68 may be formed in the peripheral well region 72. The peripheral well region 72 may be covered by the insulating layer 14. The insulating layer 14 may include a first well opening 74 and a second well opening 76 that expose the peripheral well region 72. The emitter pad 30 may contact the peripheral well region 72 through the first well opening 74. Further, the emitter finger 32 may contact the peripheral well region 72 through the second well opening 76.

The insulating layer 14 may further include a gate opening 78 between the first well opening 74 and the second well opening 76. Further, the semiconductor device 10 may further include peripheral gate wiring 80 located on the first insulating layer 50. The peripheral gate wiring 80 may be located below the peripheral gate finger 28 and above the peripheral well region 72. The peripheral gate finger 28 may contact the peripheral gate wiring 80 through the gate opening 78. The peripheral gate wiring 80 may be formed from polysilicon, which is conductive. In another example, the peripheral gate wiring 80 may be formed from any other conductive material.

### Operation and Advantages of the Semiconductor Device in Accordance with the Present Embodiment

The operation of the semiconductor device 10 in accordance with the present embodiment will now be described.

In the semiconductor device 10 in accordance with the present embodiment, the semiconductor layer 12 includes the gate-to-dummy mesa 54 defined between the gate trench 42 and the dummy trench 44. The plurality of contact plugs 64 include the contact plug row R in contact with the gate-to-dummy mesa 54. The contact plug row R at least partially overlaps the dummy trench 44 in plan view and is separated from the gate trench 42. The contact plugs 64 in the row R are spaced apart from one another in the Y-axis direction.

As shown in FIG. 6, the contact plugs 64, which are in contact with the gate-to-dummy mesa 54, are located closer to the dummy trench 44 than to the gate trench 42. This improves the short-circuit withstand capability between the first electrode 46 in the gate trench 42 and the contact plugs 64 in the row R.

The contact plug row R at least partially overlaps the dummy trench 44 in plan view. Therefore, dimension D1 of the upper portion 54A of the gate-to-dummy mesa 54 does not necessarily have to be greater than dimension D3 of each contact plug 64. This allows dimension D1 of the gate-to-dummy mesa 54 in the X-axis direction to be reduced.

Further, as shown in FIG. 7, the gate-to-dummy mesa 54 includes a plurality of p-type in-base regions 66. Each in-base region 66 is in contact with the bottom portion 64B of a corresponding contact plug 64 in the row R. The in-base regions 66 have a greater p-type impurity concentration than the second region 58A. This avoids latch-up in the semiconductor device 10 and allows the semiconductor device 10 to operate within a Reverse Bias Safe Operating Area (RBSOA).

The in-base regions 66, which have a relatively high p-type impurity concentration, inhibit the formation of an inversion layer that acts as a channel of the semiconductor device 10. The in-base regions 66 are, however, spaced apart from one another in the Y-axis direction. This results in the formation of an inversion layer in the second regions 58A of the gate-to-dummy mesas 54 at locations free from the in-base regions 66. As a result, during an ON operation of the semiconductor device 10, current paths are formed as indicated by the arrows in FIG. 7.

As shown in FIG. 6, each in-base region 66 extends across the entire width of the gate-to-dummy mesa 54 in the X-axis direction. As a result, the interruption of current paths from the third region 60A to the first region 56A is ensured in the periphery of each contact plug 64. This reduces variations in the characteristics of the semiconductor device 10.

Accordingly, the semiconductor device 10 in accordance with the present embodiment allows the dimension of the mesa 54 in the X-axis direction to be reduced while maintaining or improving the performance of the semiconductor device 10.

The semiconductor device 10 of the present embodiment has the advantages described below.
(1) The gate trench 42 (first trench) is separated from the dummy trench 44 (second trench) in the X-axis direction (second direction orthogonal to the first direction) in plan view, and the semiconductor layer 12 includes the gate-to-dummy mesa 54 (mesa) defined between the gate trench 42 and the dummy trench 44. The contact plugs 64 include the contact plug row R in contact with the gate-to-dummy mesa 54. The contact plug row R at least partially overlaps the dummy trench 44 in plan view and is separated from the gate trench 42. The contact plugs 64 in the row R are spaced apart from one another in the Y-axis direction (first direction).

In this configuration, even if the dimension D1 of the gate-to-dummy mesa 54 in the X-axis direction is relatively small, the short-circuit withstand capability between the first electrode 46 in the gate trench 42 and the contact plugs 64 in the row R is improved. Further, the contact plugs 64 in the row R are spaced apart from one another. This allows ON operations to be performed properly in the semiconductor device 10. Accordingly, the dimension of the gate-to-dummy mesa 54 in the X-axis direction can be reduced while maintaining or improving the performance of the semiconductor device 10.
(2) The gate-to-dummy mesa 54 (mesa) includes a plurality of in-base regions 66 of the p-type (second conductivity type). The in-base regions 66 have a greater p-type impurity concentration than the second region 58A. Each in-base region 66 is in contact with the bottom portion 64B of a corresponding contact plug 64 in the row R. The in-base regions 66 are spaced apart from one another in the Y-axis direction (first direction). The in-base regions 66 limit latch-up in the semiconductor device 10 and allow the semiconductor device 10 to operate within a Reverse Bias Safe Operating Area (RBSOA).
(3) Each in-base region 66 is located between the third region 60A and the first region 56A and extends across the entire width of the gate-to-dummy mesa 54 (mesa) in the X-axis direction (second direction). This configuration ensures the interruption of current paths from the third region 60A to the first region 56A in the periphery of each contact plug 64. Accordingly, variations in the characteristics of the semiconductor device 10 are reduced.
(4) Each of the contact plugs 64 in the row R extends through the third region 60A. In this configuration, the bottom portion 64B of each contact plug 64 is located at a relatively low position. This allows the semiconductor device 10 to operate within a Reverse Bias Safe Operating Area (RBSOA).
(5) The dimension of the upper portion 54A of the gate-to-dummy mesa 54 (mesa) in the X-axis direction (second direction) may be less than or equal to the dimension of each contact plug 64 in the row R in the X-axis direction (second direction). This configuration allows the gate-to-dummy mesa 54 to be reduced in size.

### Further Layout Example of the Gate Trenches and the Dummy Trenches

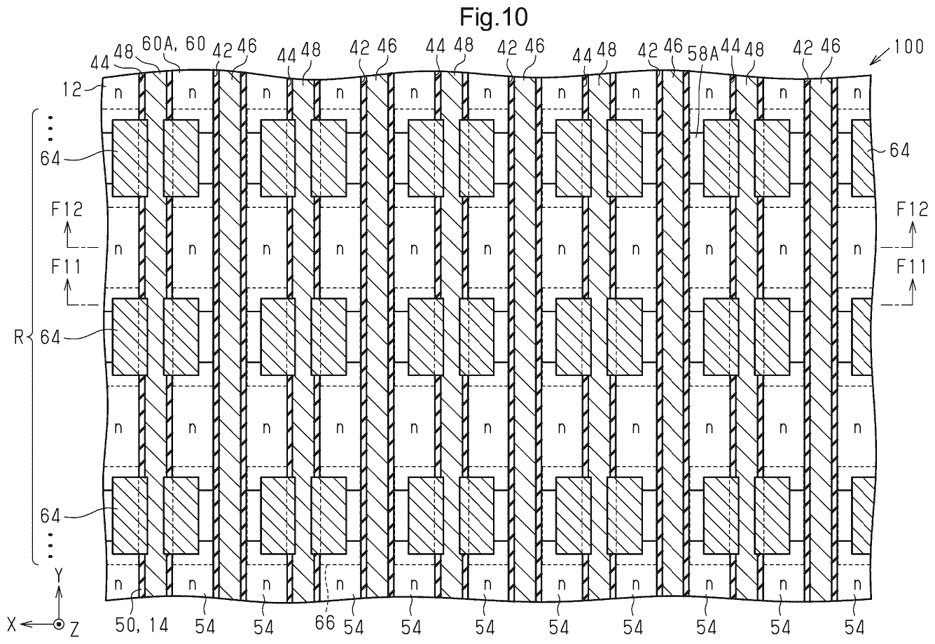

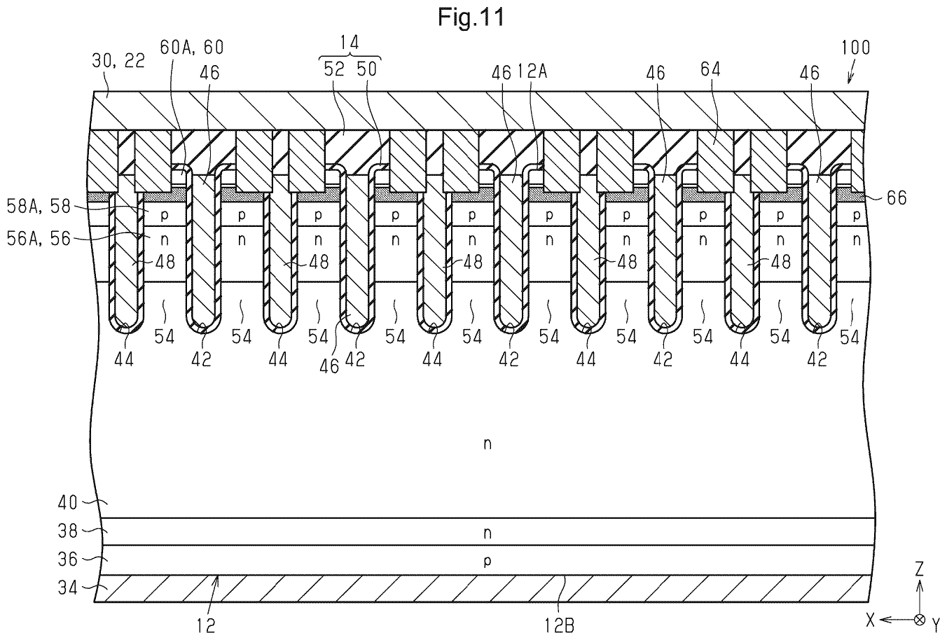

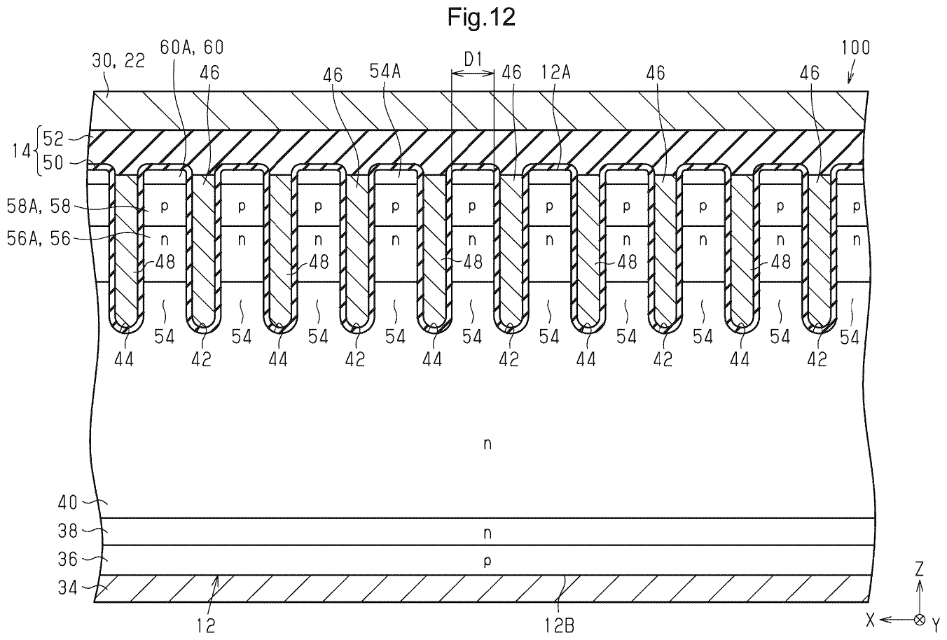

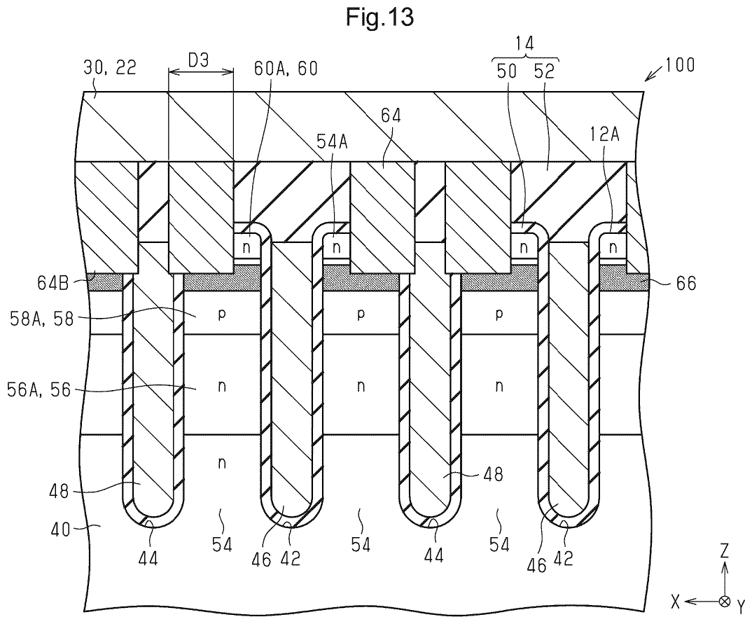

With reference to FIGS. 10 to 13, a semiconductor device 100 in accordance with a further example of the present disclosure will now be described. FIG. 10 is a schematic plan view of the semiconductor device 100. FIG. 11 is a schematic cross-sectional view of the semiconductor device 100 taken along line F11-F11 in FIG. 10. FIG. 12 is a schematic cross-sectional view of the semiconductor device 100 taken along line F12-F12 in FIG. 10. FIG. 13 is an enlarged view of a portion shown in FIG. 11. In FIGS. 10 to 13, the same reference characters are given to those elements that are the same as the corresponding elements in the first embodiment. Elements that are the same as the corresponding elements of the first embodiment will not be described in detail.

As shown in FIGS. 10 to 13, the gate trenches 42 and the dummy trenches 44 are alternately arranged in the X-axis direction. In the semiconductor device 100, two dummy trenches 44 are not adjacent to each other. Therefore, the semiconductor layer 12 does not have to include the dummy-to-dummy mesa 62 (refer to FIG. 3) of the first embodiment. As shown in FIG. 12, the trenches 42 and 44 may be arranged at equal intervals (corresponding to dimension D1 of upper portion 54A of each gate-to-dummy mesa 54).

As shown in FIG. 10, two contact plug rows R may be arranged overlapping each dummy trench 44 in plan view. As shown in FIG. 13, each second electrode 48 may contact the contact plugs 64 of the two rows R. The two contact plug rows R may be arranged close to each other on each second electrode 48.

As shown in FIGS. 10, 11, and 13, in the semiconductor device 100, the contact plug rows R may be arranged so as to be in contact with all of the mesas, that is, all of the gate-to-dummy mesas 54. Accordingly, in the semiconductor device 100, the contact plugs 64 are arranged at a higher density than the semiconductor device 10 shown in FIG. 3.

### Example in Which Each Contact Plug is in Contact with Two Mesas

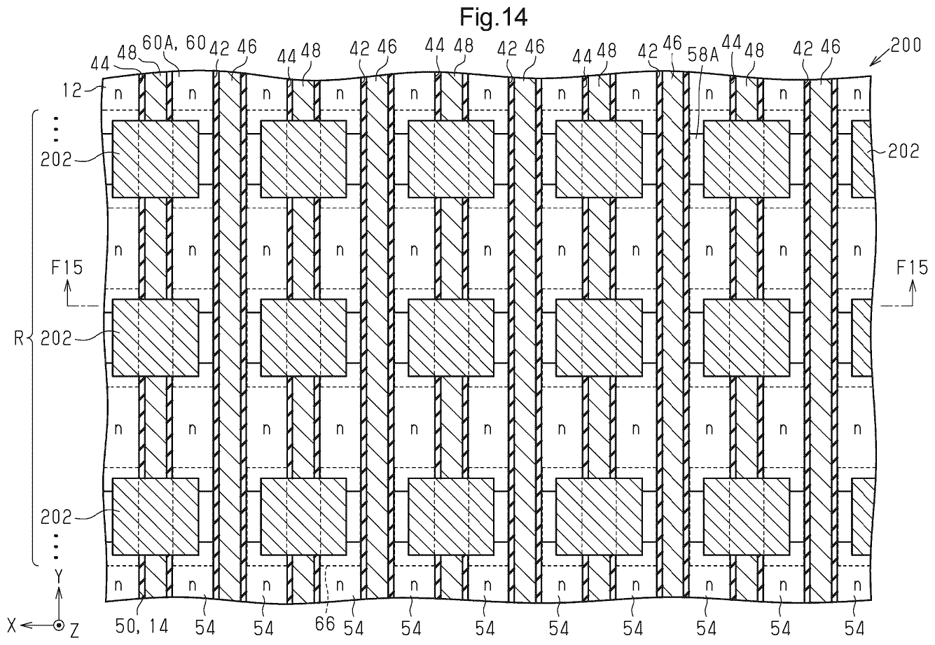

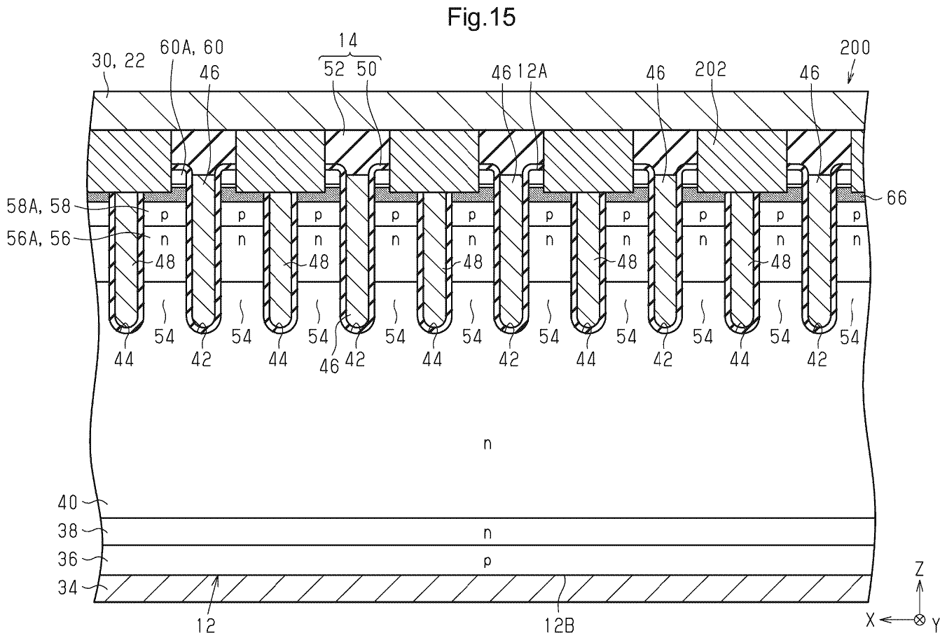

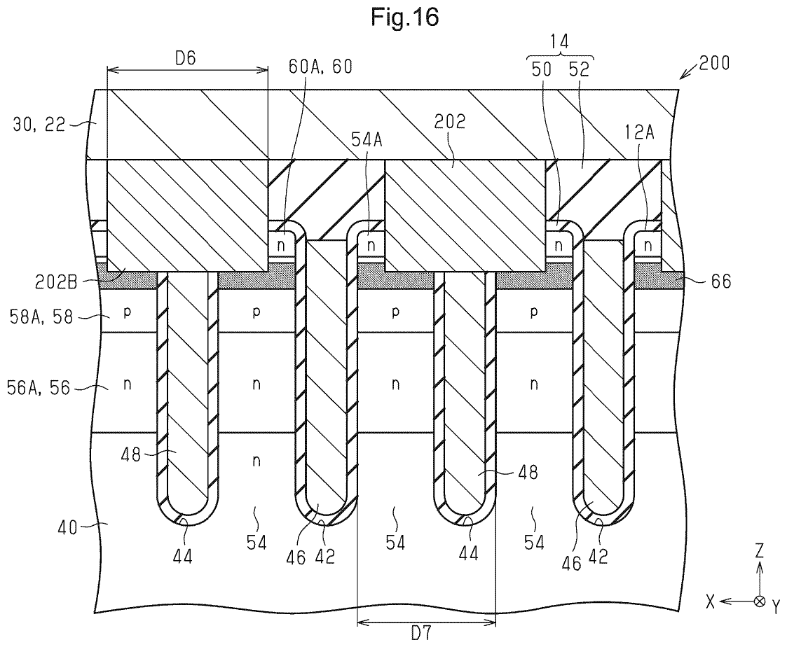

With reference to FIGS. 14 to 16, a semiconductor device 200 in accordance with a further example of the present disclosure will now be described. FIG. 14 is a schematic plan view of the semiconductor device 200. FIG. 15 is a schematic cross-sectional view of the semiconductor device 200 taken along line F15-F15 in FIG. 14. FIG. 16 is an enlarged view of a portion shown in FIG. 15. In FIGS. 14 to 16, the same reference characters are given to those elements that are the same as the corresponding elements in the first embodiment. Elements that are the same as the corresponding elements of the first embodiment will not be described in detail.

As shown in FIGS. 14 to 16, in the semiconductor device 200, the gate trenches 42 and the dummy trenches 44 are alternately arranged in the X-axis direction in the same manner as in the semiconductor device 100. The semiconductor device 200 includes a plurality of contact plugs 202 that extend through the insulating layer 14 and contact the semiconductor layer 12. The plurality of contact plugs 202 include a contact plug row R in contact with two gate-to-dummy mesas 54. Each contact plug 202 in the row R may extend through the third regions 60A of the two gate-to-dummy mesas 54. The contact plug row R is located between two gate trenches 42 in plan view and is separated from the two gate trenches 42.

The two gate-to-dummy mesas 54, which are in contact with a contact plug row R, are also referred to as a first mesa and a second mesa. When the first mesa is defined between the first trench and the second trench and the second mesa is defined between the second trench and the third trench, the first trench and the third trench correspond to the gate trenches 42. Further, the second trench corresponds to the dummy trench 44. Since the third trench corresponds to the gate trench 42, a third electrode located in the third trench is electrically connected to a first electrode located in the first trench (first electrode 46 located in gate trench 42). Each contact plug row R contacts both the first mesa and the second mesa and is separated from both the first trench and the third trench.

As shown in FIG. 16, each contact plug 202 includes a bottom portion 202B located on the second electrode 48. The bottom portion 202B of each contact plug 202 is covered by two in-base regions 66 of different gate-to-dummy mesas 54.

In the semiconductor device 200, each contact plug 202 has dimension D6 in the X-axis direction (refer to FIG. 16) that is greater than the dimension of each dummy trench 44 in the X-axis direction. In an example, as shown in FIG. 16, pitch D7 of the trenches 42 and 44 in the X-axis direction may be less than dimension D6 of each contact plug 202 in the X-axis direction.

In the illustrated example, each contact plug 202 is arranged in contact with two gate-to-dummy mesas 54. This allows dimension D1 of the upper portion 54A of each gate-to-dummy mesa 54 to be reduced in size.

### Example of In-Base Region at Different Depths

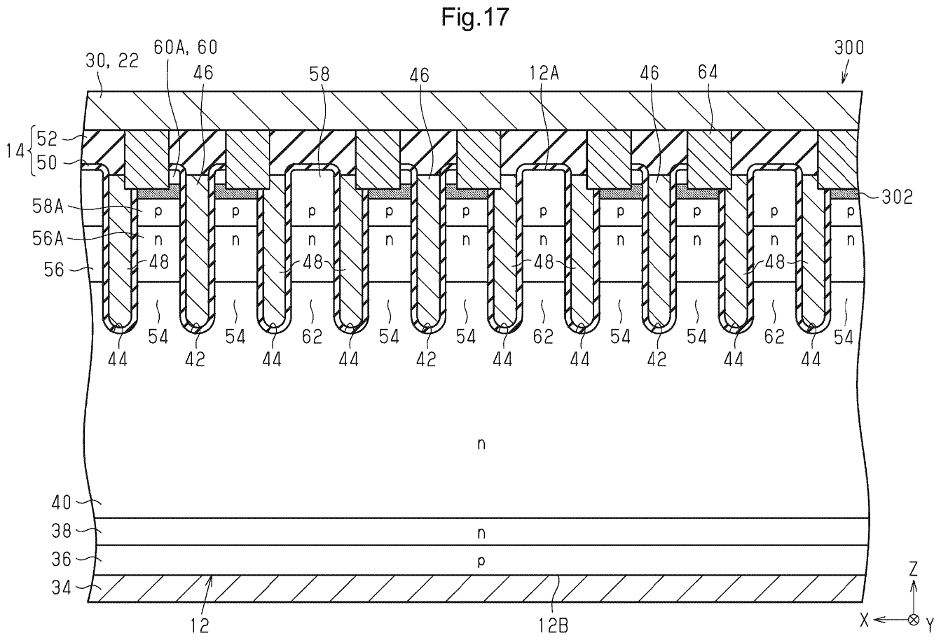

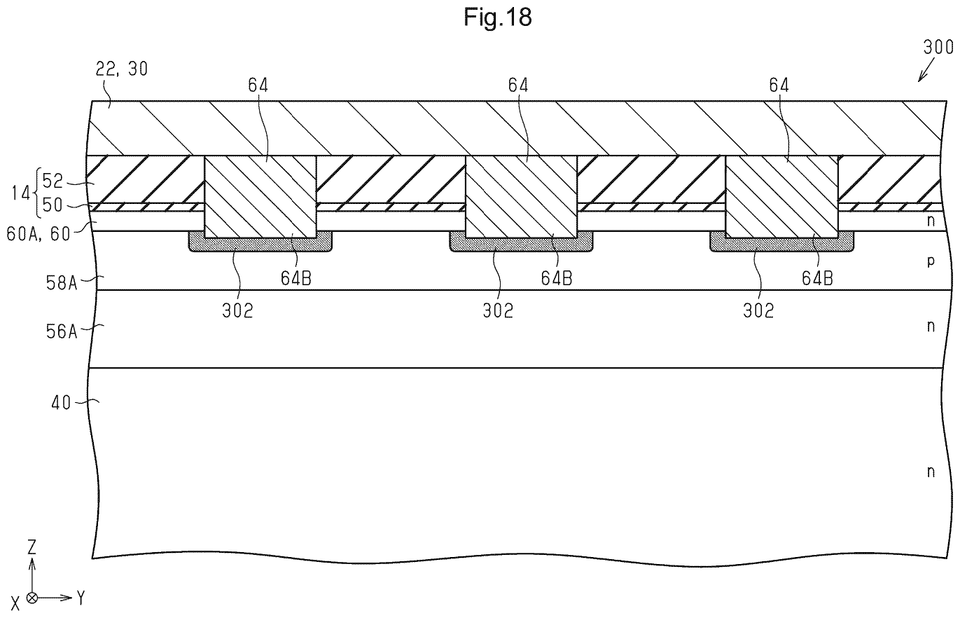

With reference to FIGS. 17 and 18, a semiconductor device 300 in accordance with a further example of the present disclosure will now be described. FIG. 17 is a schematic cross-sectional view of the semiconductor device 300. FIG. 18 is a schematic cross-sectional view of the semiconductor device 300 taken from a different direction from that of FIG. 17. In FIGS. 17 and 18, the same reference characters are given to those elements that are the same as the corresponding elements in the first embodiment. Elements that are the same as the corresponding elements of the first embodiment will not be described in detail.

As shown in FIGS. 17 and 18, the gate-to-dummy mesas 54 of the semiconductor device 300 each include p-type in-base regions 302. Each in-base region 302 is in contact with the bottom portion 64B of the corresponding contact plug 64 in the row R. The in-base regions 302 are spaced apart from one another in the Y-axis direction.

The in-base regions 302 have a greater p-type impurity concentration than the second region 58A. The p-type impurity concentration of the in-base regions 302 may be 1×10¹⁹ cm⁻³ to 1×10²⁰ cm⁻³, inclusive.

Each in-base region 302 is located between the third region 60A and the first region 56A. Each in-base region 302 is adjacent to the second region 58A. Further, each in-base region 302 is adjacent to the third region 60A.

The in-base regions 302 extend along the bottom portions 64B of the corresponding contact plugs 64 so as to cover the bottom portions 64B of the contact plugs 64. This allows the positions of the in-base regions 302 to be changed in accordance with the positions of the bottom portions 64B of the contact plugs 64. If the bottom portions 64B of the contact plugs 64 are located at relatively high positions, each in-base region 302 may be adjacent to the third region 60A as shown in the drawings. If the bottom portions 64B of the contact plugs 64 are located at relatively low positions, each in-base region 66 may be separated from the third region 60A in the Z-axis direction, as described with reference to FIG. 7.

### Second Embodiment

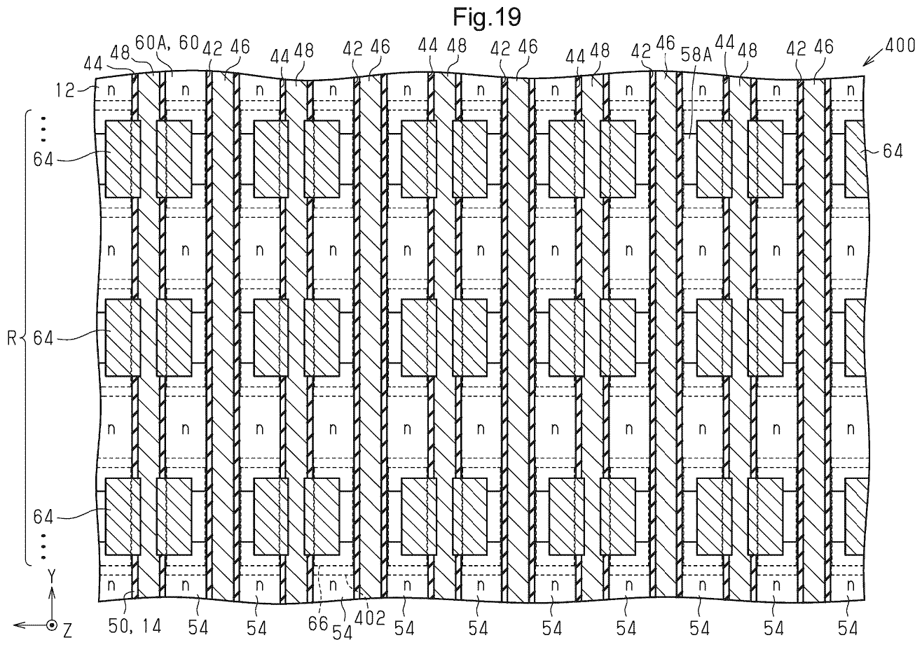

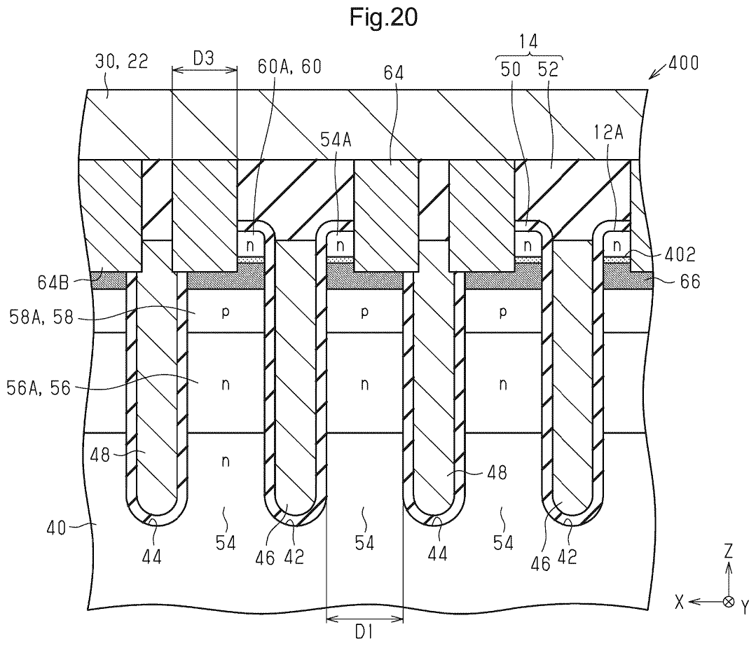

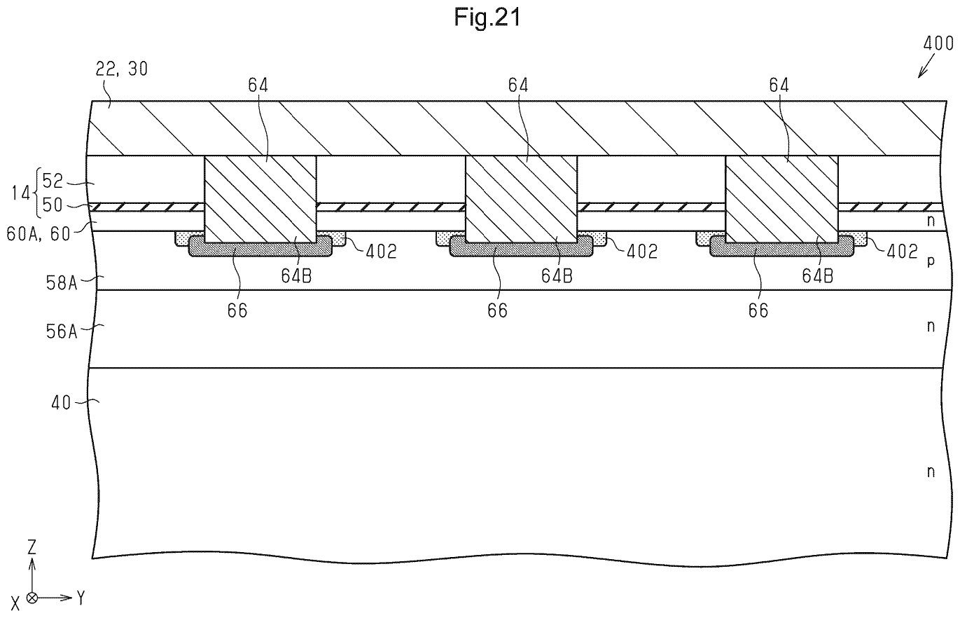

With reference to FIGS. 19 to 21, an exemplary semiconductor device 400 in accordance with a second embodiment of the present disclosure will now be described. FIG. 19 is a schematic plan view of the semiconductor device 400. FIGS. 20 and 21 are schematic cross-sectional views of the semiconductor device 400 shown in FIG. 19. In FIGS. 19 to 21, the same reference characters are given to those elements that are the same as the corresponding elements in the first embodiment. Elements that are the same as the corresponding elements of the first embodiment will not be described in detail.

As shown in FIGS. 19 to 21, in the semiconductor device 400, each gate-to-dummy mesa 54 further includes p-type complementary regions 402. The p-type impurity concentration of the complementary regions 402 is greater than the p-type impurity concentration of the second region 58A and less than the p-type impurity concentration of the in-base regions 66. In an example, the p-type impurity concentration of the complementary regions 402 may be 1×10¹⁸ cm⁻³ to 1×10¹⁹ cm⁻³, inclusive. Each complementary region 402 at least partially surrounds one of the in-base regions 66 in plan view. Each complementary region 402 may extend over the entire width of the gate-to-dummy mesa 54 in the X-axis direction.

As shown in FIGS. 20 and 21, each complementary region 402 is located between the third region 60A and the first region 56A. Each complementary region 402 is adjacent to the second region 58A. Each complementary region 402 may be located in the second region 58A closer to the third region 60A than to the first region 56A. In the illustrated example, each complementary region 402 may be adjacent to the third region 60A. The complementary regions 402 may be located above the in-base regions 66.

### Operation and Advantages of the Semiconductor Device in Accordance with the Present Embodiment

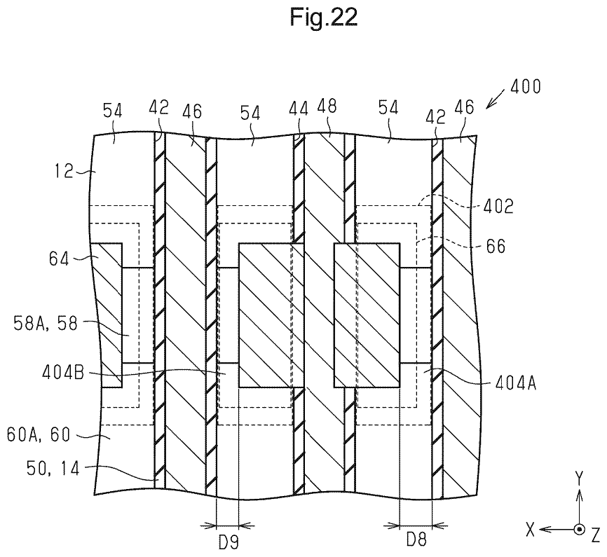

With reference to FIGS. 22 to 25, the operation of the semiconductor device 400 will now be described.

As described below, the complementary regions 402 of the semiconductor device 400 act to reduce variations in the characteristics of the semiconductor device 400 that may be caused if the pattern of the contact plugs 64 is misaligned in the manufacturing process.

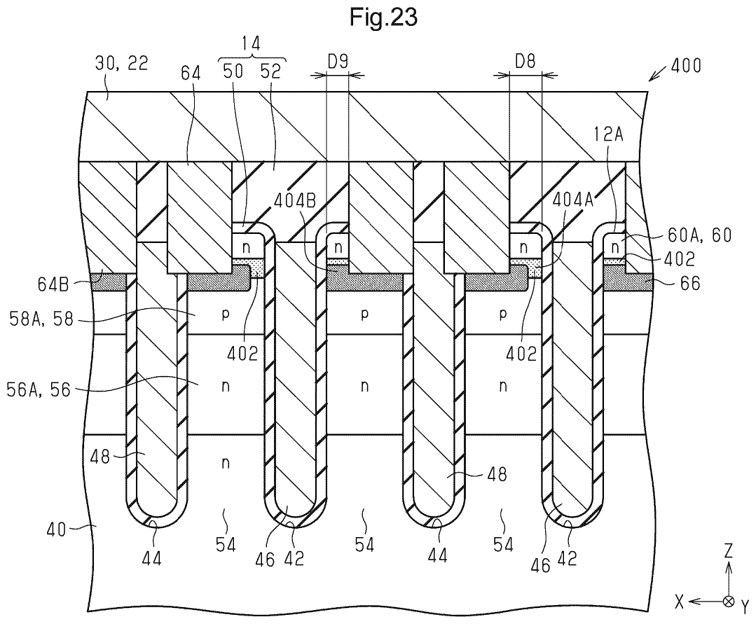

FIG. 22 is an enlarged plan view of the semiconductor device 400 showing a state in which the contact plugs 64 are misaligned in the X-direction. FIG. 23 is a schematic cross-sectional view of the semiconductor device 400 shown in FIG. 22. As shown in FIGS. 22 and 23, the contact plugs 64 are misaligned toward the left with respect to the trenches 42 and 44. In this case, the contact plugs 64 still remain in contact with the gate-to-dummy mesas 54. However, the gate trenches 42 are spaced apart from the contact plugs 64 by a relatively large distance D8 and a relatively small distance D9 in accordance with the positional relationship of the gate trenches 42 and the contact plugs 64. Accordingly, a relatively wide area 404A extends between the gate trench 42 and the contact plug 64 that are separated by the relatively large distance D8, and a relatively narrow area 404B extends between the gate trench 42 and the contact plug 64 that are separated by the relatively small distance D9.

Since the in-base regions 66 are formed along the bottom portions 64B of the contact plugs 64, the positions of the in-base regions 66 are in accordance with the positions of the contact plugs 64. This is because the in-base regions 66 are formed by implanting ions through contact holes receiving the contact plugs 64. Therefore, when the contact plugs 64 are misaligned during formation, the in-base regions 66 are also misaligned.

For the reason described above, as shown in FIGS. 22 and 23, the in-base region 66 may be able to extend over the entire length of the relatively narrow area 404B in the X-axis direction but may not be able to extend over a part of the length of the relatively wide area 404A in the X-axis direction. In the illustrated example, the portion of the area 404A adjacent to the gate trench 42 and relatively far from the contact plug 64 does not include the in-base region 66.

In this respect, each complementary region 402 extends across the entire width of the gate-to-dummy mesa 54 in the X-axis direction. In an example, the complementary regions 402 may be formed by implanting ions with a mask before forming the contact holes for the contact plugs 64. Accordingly, even if the contact plugs 64 are misaligned, each complementary region 402 extends across the entire length of relatively wide area 404A in the X-axis direction.

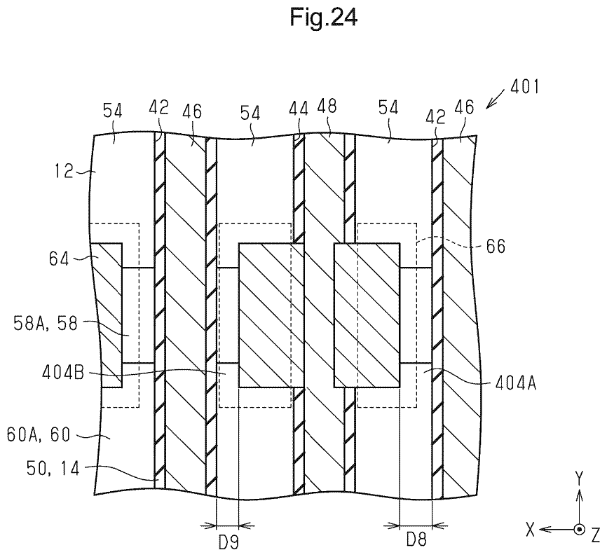

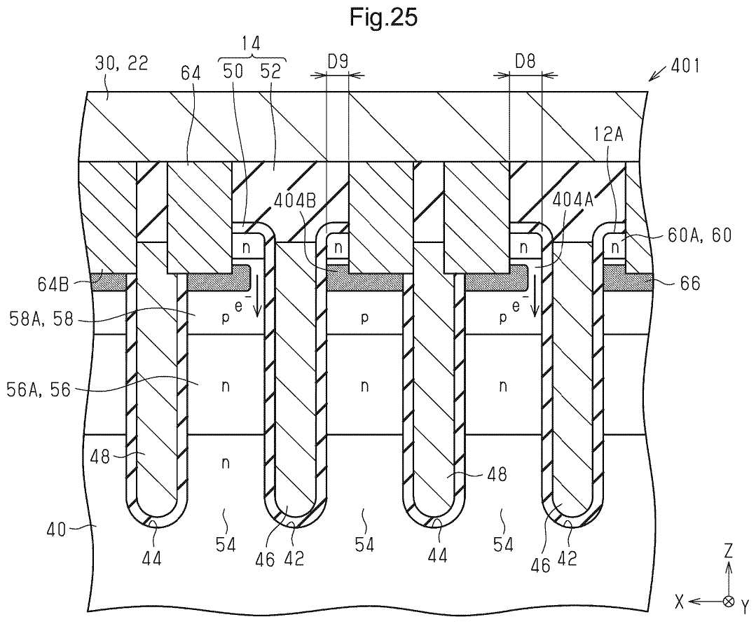

A semiconductor device 401 lacking complementary regions will now be described for comparison. FIG. 24 is an enlarged plan view of the semiconductor device 401 showing a state in which the contact plugs 64 are misaligned in the X-direction. FIG. 25 is a schematic cross-sectional view of the semiconductor device 401 shown in FIG. 24.

As shown in FIGS. 24 and 25, the contact plugs 64 are misaligned toward the left with respect to the trenches 42 and 44 in the same manner as in FIGS. 22 and 23. As a result, the relatively wide area 404A extends between the gate trench 42 and the contact plug 64 that are separated by the relatively large distance D8, and the relatively narrow area 404B extends between the gate trench 42 and the contact plug 64 that are separated by the relatively small distance D9. The portion of the area 404A adjacent to the gate trench 42 and relatively far from the contact plug 64 does not include the in-base region 66.

The semiconductor device 401 lacks the complementary regions of the semiconductor device 400. Accordingly, during an ON operation of the semiconductor device 401, an inversion layer formed in the second region 58A provides current paths extending from the third region 60A through the area 404A to the first region 56A (refer to the arrows in FIG. 25). Such unintended current paths formed when the contact plugs 64 are misaligned cause variations in the characteristics of the semiconductor device 401.

In this respect, even if the contact plugs 64 are misaligned in the semiconductor device 400 in accordance with the present embodiment, the complementary region 402 extends across the entire length of the relatively wide area 404A in the X-axis direction. The complementary region 402, which has a higher p-type impurity concentration than the second region 58A, obviates the formation of the unintended current paths (inversion layer) described above. Accordingly, the semiconductor device 400 in accordance with the present embodiment has the same advantages as the first embodiment while further reducing characteristic variations.

### Modified Example of the Second Embodiment

Complementary regions such as those described in the second embodiment may be applied to a semiconductor device having a configuration differing from that of FIG. 19.

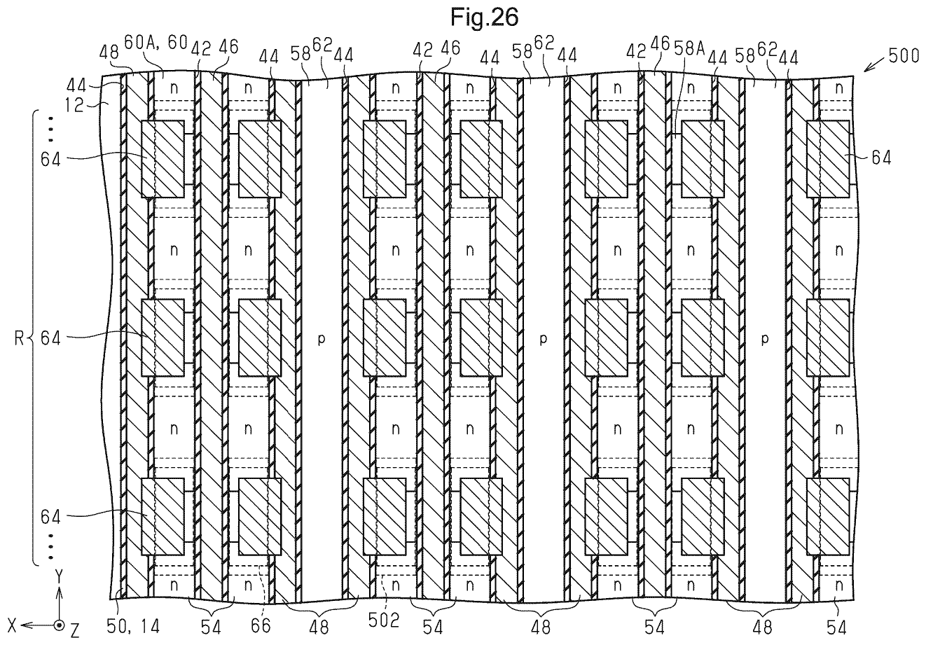

FIG. 26 is a schematic plan view of a semiconductor device 500 formed by applying complementary regions 502 to the semiconductor device 100 shown in FIG. 10. As shown in FIG. 26, in the semiconductor device 500, the gate-to-dummy mesa 54 includes a plurality of p-type complementary regions 502. The p-type impurity concentration of the complementary regions 502 is greater than the p-type impurity concentration of the second region 58A and less than the p-type impurity concentration of the in-base regions 66. In an example, the p-type impurity concentration of the complementary regions 502 may be 1×10¹⁸ cm⁻³ to 1×10¹⁹ cm⁻³, inclusive. Each complementary region 502 at least partially surrounds one of the in-base regions 66 in plan view. Each complementary region 502 may extend over the entire width of the gate-to-dummy mesa 54 in the X-axis direction. The complementary regions 502 may be located at the same positions in the Z-axis direction as the complementary regions 402 shown in FIG. 21.

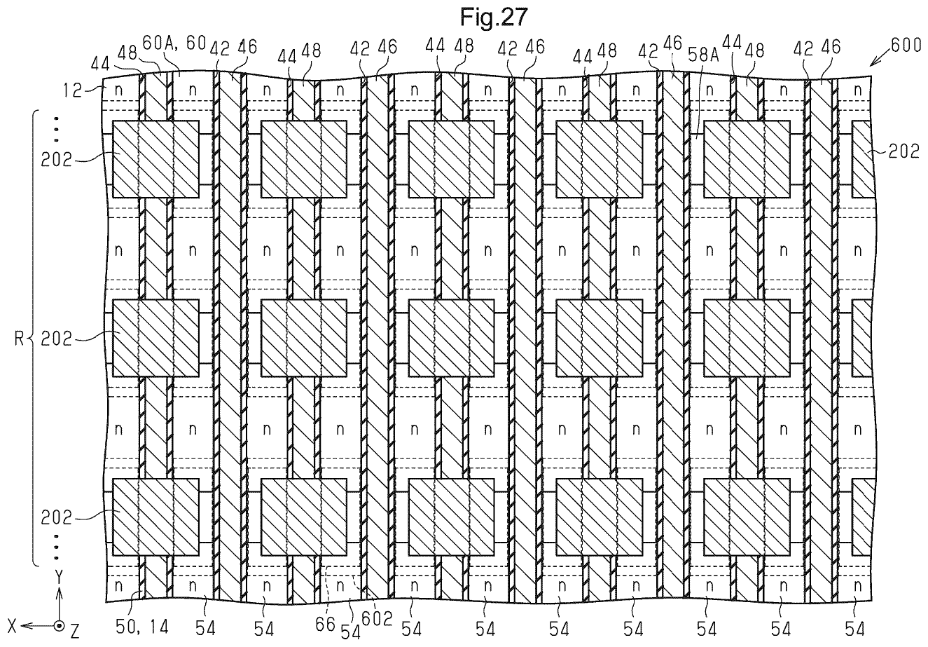

FIG. 27 is a schematic plan view of a semiconductor device 600 formed by applying complementary regions 602 to the semiconductor device 200 shown in FIG. 14. As shown in FIG. 27, in the semiconductor device 600, the gate-to-dummy mesa 54 includes a plurality of p-type complementary regions 602. The p-type impurity concentration of the complementary regions 602 is greater than the p-type impurity concentration of the second region 58A and less than the p-type impurity concentration of the in-base regions 66. In an example, the p-type impurity concentration of the complementary regions 602 may be 1×10¹⁸ cm⁻³ to 1×10¹⁹ cm⁻³, inclusive. Each complementary region 602 at least partially surrounds one of the in-base regions 66 in plan view. Each complementary region 602 may extend over the entire width of the gate-to-dummy mesa 54 in the X-axis direction. The complementary regions 602 may be located at the same positions in the Z-axis direction as the complementary regions 402 shown in FIG. 21.

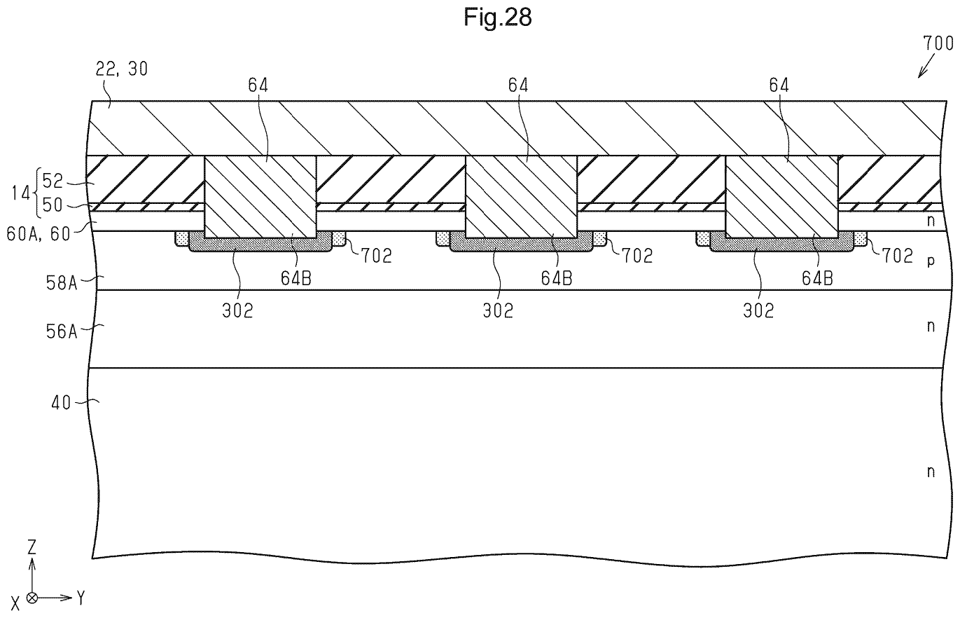

FIG. 28 is a schematic cross-sectional view of a semiconductor device 700 formed by applying complementary regions 702 to the semiconductor device 300 shown in FIG. 18. As shown in FIG. 28, in the semiconductor device 700, the gate-to-dummy mesa 54 includes a plurality of p-type complementary regions 702. The p-type impurity concentration of the complementary regions 702 is greater than the p-type impurity concentration of the second region 58A and less than the p-type impurity concentration of the in-base regions 302. In an example, the p-type impurity concentration of the complementary regions 702 may be 1×10¹⁸ cm⁻³ to 1×10¹⁹ cm⁻³, inclusive. Each complementary region 702 at least partially surrounds one of the in-base regions 302 in plan view. Each complementary region 702 may extend over the entire width of the gate-to-dummy mesa 54 in the X-axis direction. Each complementary region 702 is located between the third region 60A and the first region 56A. Each complementary region 702 is adjacent to the second region 58A. Each complementary region 702 may be located in the second region 58A closer to the third region 60A than to the first region 56A. In the illustrated example, each complementary region 702 and each in-base region 302 may be adjacent to the third region 60A. Accordingly, the complementary regions 702 need not be located above the in-base regions 302.

The principle described in the second embodiment allows the semiconductor devices 500, 600, and 700 to have the advantages of the first embodiment while further reducing characteristic variations.

### Third Embodiment

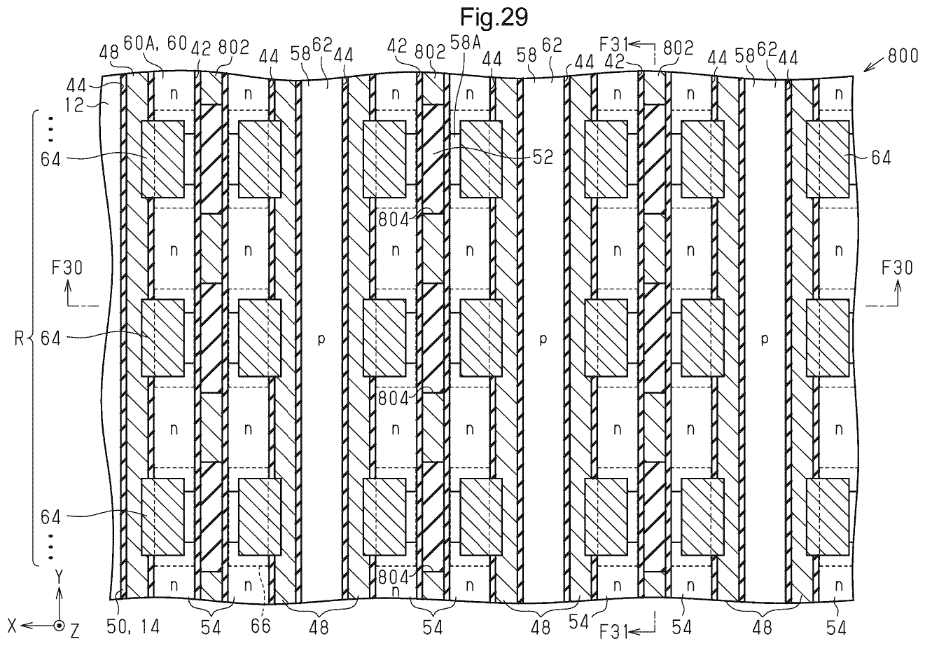

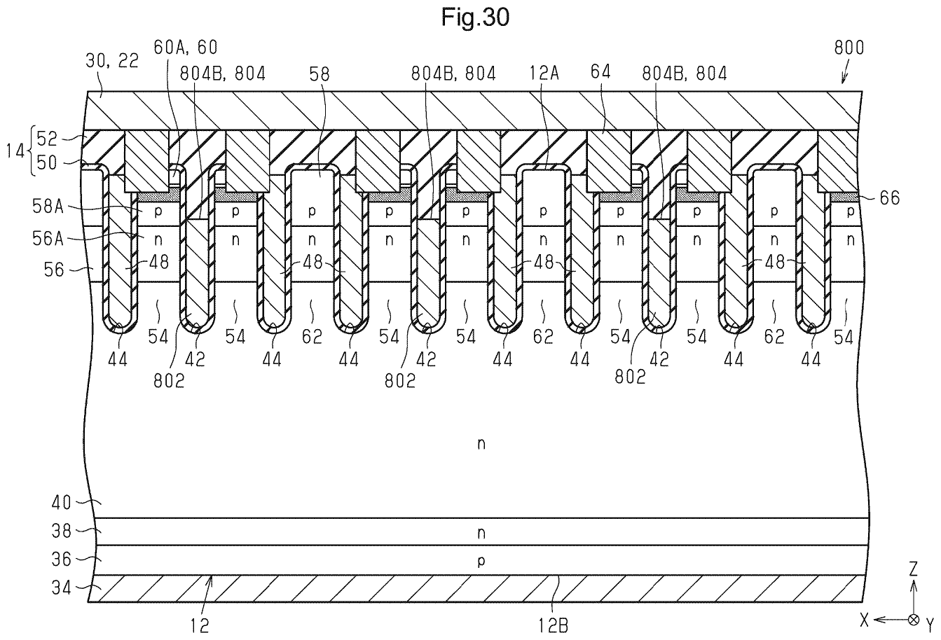

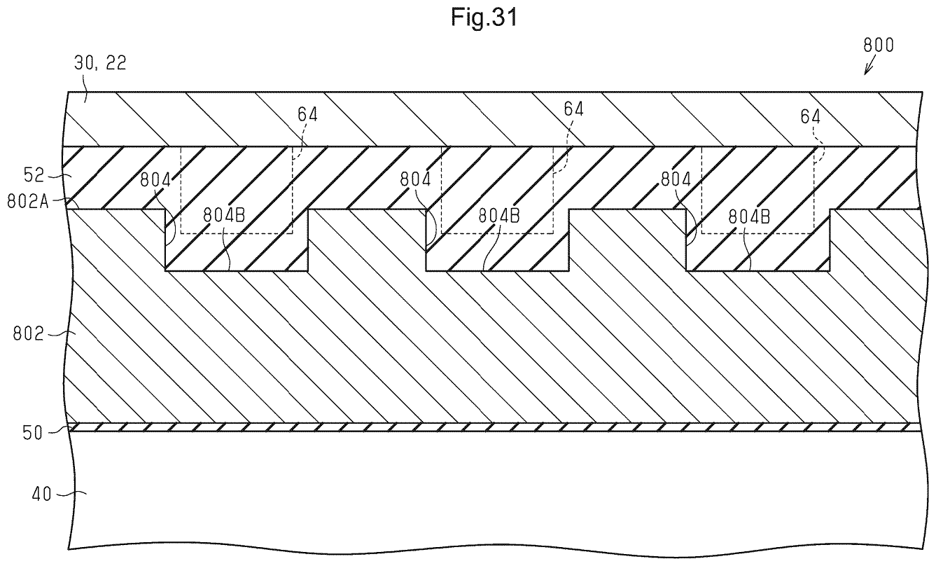

With reference to FIGS. 29 to 31, an exemplary semiconductor device 800 in accordance with a third embodiment of the present disclosure will now be described. FIG. 29 is a schematic plan view of the semiconductor device 800. FIG. 30 is a schematic cross-sectional view of the semiconductor device taken along line F30-F30 in FIG. 29. FIG. 31 is a schematic cross-sectional view of the semiconductor device taken along line F31-F31 in FIG. 29. In FIGS. 29 to 31, the same reference characters are given to those elements that are the same as the corresponding elements in the first embodiment. Elements that are the same as the corresponding elements of the first embodiment will not be described in detail.

As shown in FIGS. 29 to 31, the semiconductor device 800 includes a first electrode 802 located in each gate trench 42 and separated from the semiconductor layer 12 by the insulating layer 14. The first electrode 802 includes recesses 804. As shown in FIG. 31, the recesses 804 are recessed from an upper surface 802A of the first electrode 802. The recesses 804 are arranged in the Y-axis direction such that each recess 804 is proximate to a corresponding one of the contact plugs 64 in the row R. As shown in FIG. 29, the dimension of each recess 804 in the Y-axis direction may be greater than or equal to the dimension of each in-base region 66 in the Y-axis direction. In the illustrated example, the dimension of each recess 804 in the Y-axis direction is slightly greater than the dimension of each in-base region 66 in the Y-axis direction.

As shown in FIG. 30, each recess 804 includes a bottom surface 804B located below the interface between the third region 60A and the second region 58A. More preferably, the bottom surface 804B of each recess 804 may be located below the in-base regions 66, as in the illustrated example. Each recess 804 may be filled with the second insulating layer 52.

### Operation and Advantages of the Semiconductor Device in Accordance with the Present Embodiment

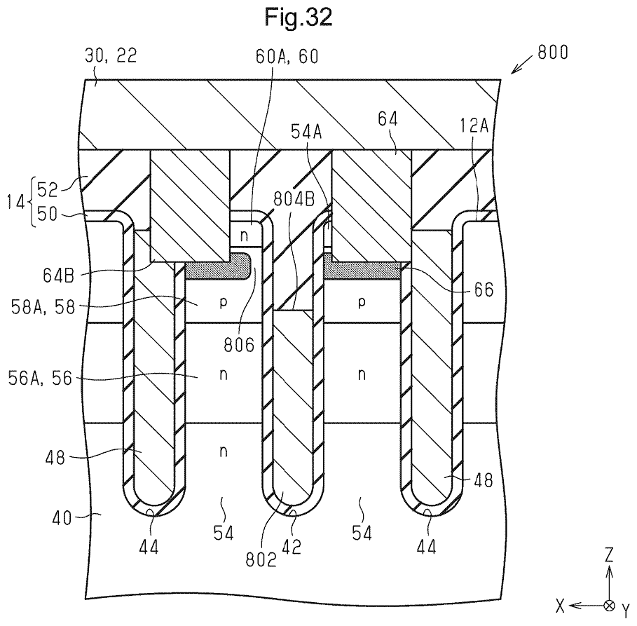

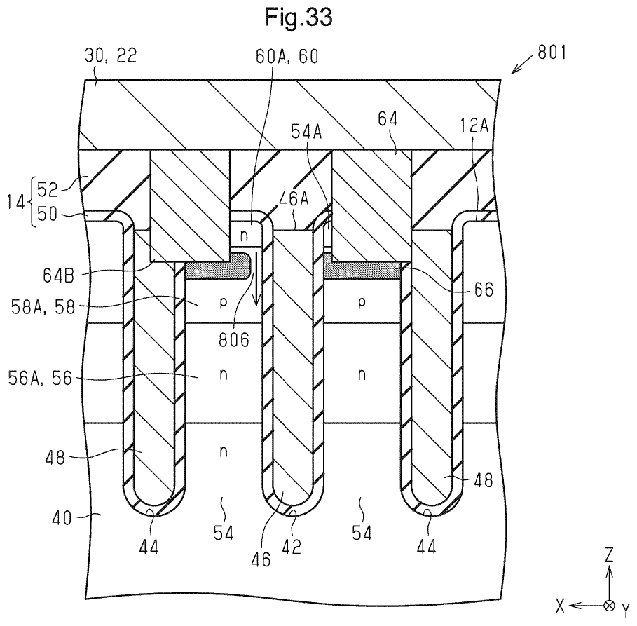

With reference to FIGS. 32 and 33, the operation of the semiconductor device 800 will now be described.

As described below, the recesses 804 of the first electrodes 802 act to reduce variations in the characteristics of the semiconductor device 800 that may be caused if the pattern of the contact plugs 64 is misaligned in the manufacturing process.

FIG. 32 is a schematic cross-sectional view of the semiconductor device 800 showing a state in which the contact plugs 64 are misaligned in the X-direction. As shown in FIG. 32, the contact plugs 64 are misaligned toward the left with respect to the trenches 42 and 44. As a result, each gate trench 42 is spaced apart from the contact plug 64 at the left side of the gate trench 42 by a relatively large distance.

The in-base regions 66, which have a relatively high p-type impurity concentration, inhibit the formation of an inversion layer that acts as a channel of the semiconductor device 10. In a normal state, the in-base regions 66 ensure the interruption of current paths from the third region 60A to the first region 56A in the periphery of the contact plugs 64. However, when the contact plugs 64 are misaligned toward the left of the trenches 42 and 44, as shown in the example of FIG. 32, each in-base region 66 located at the left side of a gate trench 42 will not extend over the entire width of the corresponding gate-to-dummy mesa 54 in the X-axis direction. A gate-adjacent region 806 between the in-base region 66 and the gate trench 42 is a part of the second region 58A. In the semiconductor device 800, the arrangement of the recesses 804 in the first electrode 802 results in the gate-adjacent region 806 facing, via the first insulating layer 50, the second insulating layer 52 and not the first electrode 802. This avoids the formation of an inversion layer in the gate-adjacent region 806 even when a gate voltage is applied to the first electrode 802.

A comparative example in which a semiconductor device 801 includes first electrodes 46 that lack recesses will now be described. FIG. 33 is a schematic cross-sectional view of the semiconductor device 801 showing a state in which the contact plugs 64 are misaligned in the X-direction. As shown in FIG. 33, the contact plugs 64 are misaligned toward the left with respect to the trenches 42 and 44 in the same manner as in the example shown in FIG. 32. As a result, each gate trench 42 is spaced apart from the contact plug 64 at the left side of the gate trench 42 by a relatively large distance. Accordingly, the in-base region 66 located at the left side of the gate trench 42 does not extend over the entire width of the corresponding gate-to-dummy mesa 54 in the X-axis direction.

The first electrodes 46 of the semiconductor device 801 lack the recesses described for the semiconductor device 800. Each first electrode 46 includes an upper surface 46A located above an interface between the third region 60A and the second region 58A. Accordingly, the gate-adjacent region 806 between the in-base region 66 and the gate trench 42 faces, via the first insulating layer 50, the first electrode 46. As a result, in the semiconductor device 801, an inversion layer is formed in the gate-adjacent region 806 when a gate voltage is applied to the first electrode 46. Accordingly, during an ON operation of the semiconductor device 801, the inversion layer formed in the second region 58A provides current paths extending from the third region 60A through the gate-adjacent region 806 to the first region 56A (refer to the arrows in FIG. 33). Such unintended current paths formed when the contact plugs 64 are misaligned cause variations in the characteristics of the semiconductor device 801.

In this respect, each first electrode 802 in the semiconductor device 800 in accordance with the present embodiment includes the recesses 804. Therefore, the first electrode 802 does not face the gate-adjacent region 806 in the X-axis direction. Accordingly, even if the contact plugs 64 are misaligned, an inversion layer is not formed in the second region 58A. This avoids the formation of unintended current paths (inversion layer). In this manner, the semiconductor device 800 in accordance with the present embodiment has the same advantages as the first embodiment while further reducing characteristic variations.

### Modified Examples of the Third Embodiment

First electrodes that include recesses such as those described in the third embodiment may be applied to a semiconductor device having a configuration differing from that of FIG. 29.

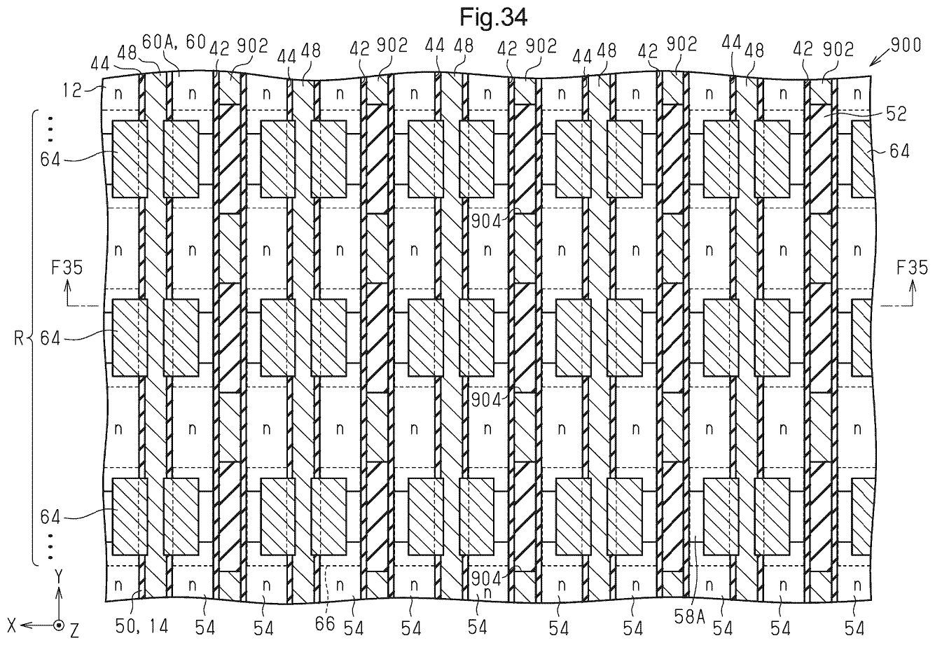

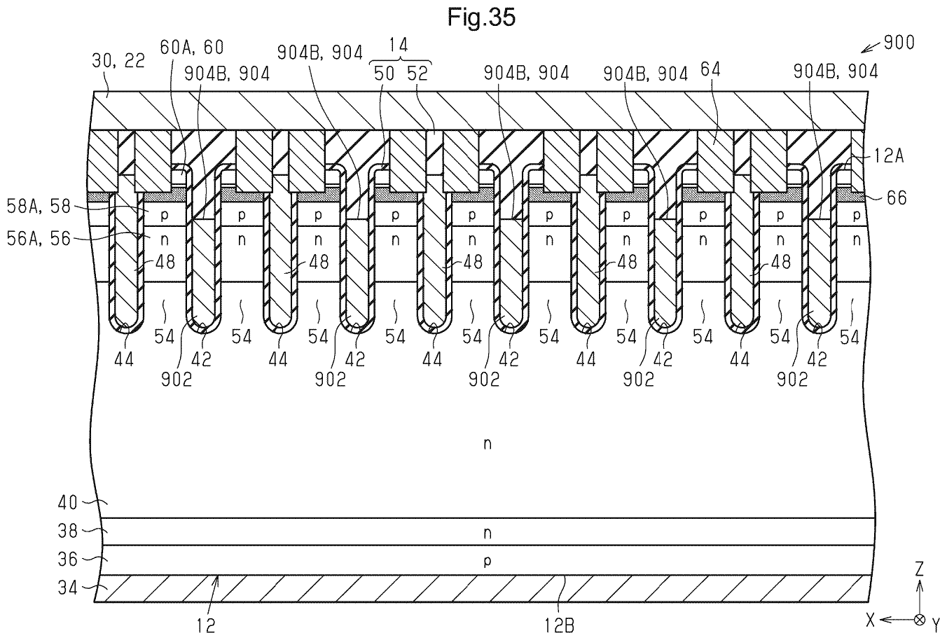

FIG. 34 is a schematic plan view of a semiconductor device 900 formed by applying first electrodes 902, each including recesses 904, to the semiconductor device 100 shown in FIG. 10. FIG. 35 is a schematic cross-sectional view of the semiconductor device taken along line F35-F35 in FIG. 34.

As shown in FIGS. 34 and 35, the semiconductor device 900 includes a first electrode 902 located in each gate trench 42 and separated from the semiconductor layer 12 by the insulating layer 14. The first electrode 902 includes the recesses 904. The recesses 904 are arranged in the Y-axis direction such that each recess 904 is proximate to a corresponding one of the contact plugs 64 in the row R, in the same manner as in the third embodiment illustrated in FIG. 31. As shown in FIG. 34, the dimension of each recess 904 in the Y-axis direction may be greater than or equal to the dimension of each in-base region 66 in the Y-axis direction.

As shown in FIG. 35, each recess 904 includes a bottom surface 904B located below the interface between the third region 60A and the second region 58A. More preferably, the bottom surface 904B of each recess 904 may be located below the in-base regions 66, as in the illustrated example. Each recess 904 may be filled with the second insulating layer 52.

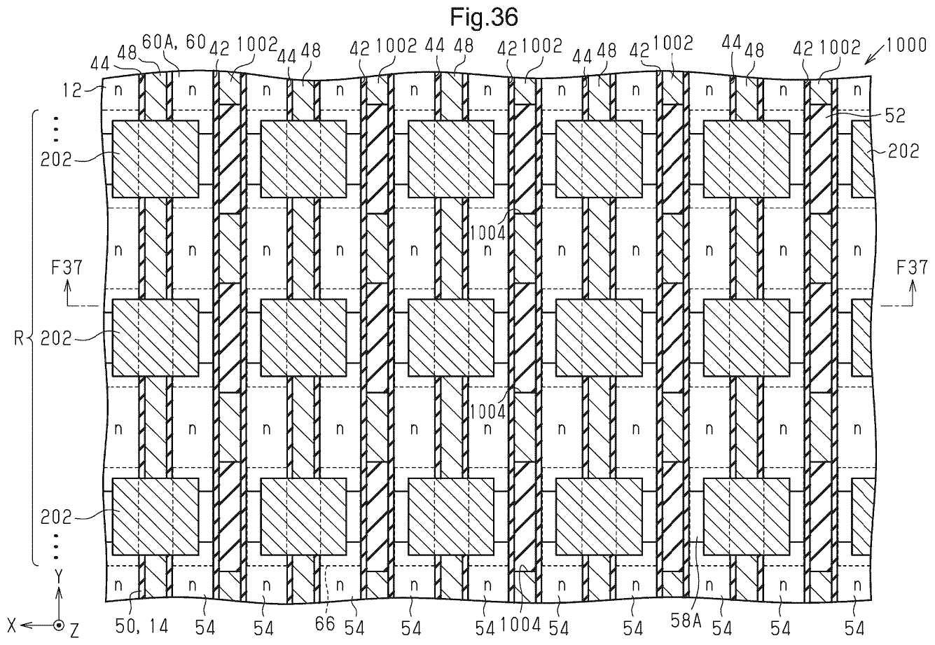

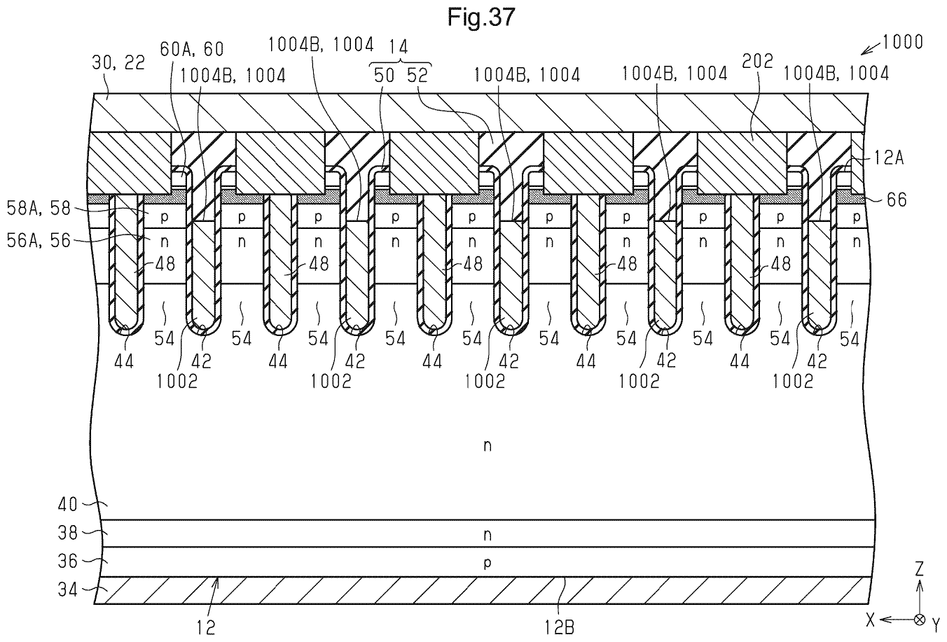

FIG. 36 is a schematic plan view of a semiconductor device 1000 formed by applying first electrodes 1002, each including recesses 1004, to the semiconductor device 200 shown in FIG. 14. FIG. 37 is a schematic cross-sectional view of the semiconductor device taken along line F37-F37 in FIG. 36.

As shown in FIGS. 36 and 37, the semiconductor device 1000 includes a first electrode 1002 located in each gate trench 42 and separated from the semiconductor layer 12 by the insulating layer 14. The first electrode 1002 includes the recesses 1004. The recesses 1004 are arranged in the Y-axis direction such that each recess 1004 is proximate to a corresponding one of the contact plugs 202 in the row R, in the same manner as in the third embodiment illustrated in FIG. 31. As shown in FIG. 36, the dimension of each recess 1004 in the Y-axis direction may be greater than or equal to the dimension of each in-base region 66 in the Y-axis direction.

As shown in FIG. 37, each recess 1004 includes a bottom surface 1004B located below the interface between the third region 60A and the second region 58A. More preferably, the bottom surface 1004B of each recess 1004 may be located below the in-base regions 66, as in the illustrated example. Each recess 1004 may be filled with the second insulating layer 52.

The principle described in the third embodiment allows the semiconductor devices 900 and 1000 to have the advantages of the first embodiment while further reducing characteristic variations.

### Other Modified Examples

In the examples described above, the ratio of the number of the gate trenches 42 to the number of the dummy trenches 44 is 1:2 or 1:1. The present disclosure, however, is not limited to these examples. Any number of dummy trenches 44 may be arranged between two gate trenches 42.

The two gate trenches 42, between which any number of dummy trenches 44 are arranged, are referred to as a left gate trench and a right gate trench. In this case, the trenches 42 and 44 include one or more dummy trenches 44 arranged between the left gate trench and the right gate trench. Among the one or more dummy trenches 44, the dummy trench 44 located closest to the left gate trench at least partially overlaps a contact plug row R in plan view. In the same manner, among the one or more dummy trenches 44, the dummy trench 44 located closest to the right gate trench at least partially overlaps another contact plug row R in plan view.

One or more of the examples described in this specification may be combined as long as there is no technical contradiction.

In this specification, “at least one of A and B” should be understood to mean “only A, only B, or both A and B.”

In this specification, the word “on” includes the meaning of “on” in addition to the meaning of “above” unless otherwise described in the context. Accordingly, the phrase “first layer formed on second layer” may mean that the first layer is formed directly contacting the second layer in one embodiment and that the first layer is located above the second layer without contacting the second layer in another embodiment. Thus, the word “on” will also allow for a structure in which another layer is arranged between the first layer and the second layer.

The terms used in this specification to indicate directions such as vertical, horizontal, upward, downward, up, down, forward, rearward, side, left, right, front, and back will be attributed to specific directions of the described and illustrated device. In this disclosure, a variety of alternative directions may be available for any given direction. Thus, directional terms should not be construed narrowly.

The Z-axis direction, for example, as referred to in this specification does not necessarily have to be the vertical direction and does not necessarily have to fully coincide with the vertical direction. Accordingly, in the structures disclosed above (e.g., structure shown in FIG. 1), upward and downward in the Z-axis direction as referred to in this specification is not limited to upward and downward in the vertical direction. For example, the X-axis direction may be the vertical direction. Alternatively, the Y-axis direction may be the vertical direction.

### Clauses

Technical concepts that can be understood from each of the above embodiments and modified examples will now be described. Reference characters used in the described embodiment are added to corresponding elements in the clauses to aid understanding without any intention to impose limitations on these elements. The reference characters are given as examples to aid understanding and are not intended to limit elements to the elements denoted by the reference characters.

### Clause 1

A semiconductor device, including:
a semiconductor layer (12) including a first surface (12A);
a first trench (42) and a second trench (44) extending from the first surface (12A) into the semiconductor layer (12);
an insulating layer (14) located on the semiconductor layer (12);
a first electrode (46) located in the first trench (42) and separated from the semiconductor layer (12) by the insulating layer (14);
a second electrode (48) located in the second trench (44) and separated from the semiconductor layer (12) by the insulating layer (14), the second electrode (48) being electrically insulated from the first electrode (46); and
contact plugs (64) extending through the insulating layer (14) and contacting the semiconductor layer (12), where:
the first trench (42) and the second trench (44) each extend in a first direction in plan view, the first trench (42) is separated from the second trench (44) in a second direction that is orthogonal to the first direction in plan view, and the semiconductor layer (12) includes a mesa (54) defined between the first trench (42) and the second trench (44); and
the contact plugs (64) include a contact plug row (R) in contact with the mesa (54), the contact plug row (R) at least partially overlaps the second trench (44) in plan view and is separated from the first trench (42), and the contact plugs (64) in the row (R) are spaced apart from one another in the first direction.

### Clause 2

The semiconductor device according to clause 1, where:
the mesa (54) includes
   a first region (56A) of a first conductivity type,
   a second region (58A) of a second conductivity type located on the first region (56A),
   a third region (60A) of the first conductivity type located on the second region (58A) and including a portion of the first surface (12A) of the semiconductor layer (12), and
   a plurality of in-base regions (66) of the second conductivity type, the plurality of in-base regions (66) having a greater second conductivity type impurity concentration than the second region (58A); and
each of the plurality of in-base regions (66) is in contact with a bottom portion (64B) of a corresponding one of the contact plugs (64) in the row (R), and the plurality of in-base regions (66) are spaced apart from one another in the first direction.

### Clause 3

The semiconductor device according to clause 2, where each of the plurality of in-base regions (66) is located between the third region (60A) and the first region (56A) and extends across an entire width of the mesa (54) in the second direction.

### Clause 4

The semiconductor device according to clause 2, where each of the contact plugs (64) in the row (R) extends through the third region (60A).

### Clause 5

The semiconductor device according to any one of clauses 1 to 4, where each of the contact plugs (64) in the row (R) is in contact with the second electrode (48).

### Clause 6

The semiconductor device according to any one of clauses 1 to 5, where the contact plugs (64) in the row (R) are arranged at constant intervals in the first direction.

### Clause 7

The semiconductor device according to any one of clauses 1 to 6, where the mesa (54) includes an upper portion (54A) including a portion of the first surface (12A) of the semiconductor layer (12), the upper portion (54A) of the mesa (54) having a dimension (D1) in the second direction that is less than or equal to 0.8 μm.

### Clause 8

The semiconductor device according to any one of clauses 1 to 7, where the mesa (54) includes an upper portion (54A) including a portion of the first surface (12A) of the semiconductor layer (12), the upper portion (54A) of the mesa (54) having a dimension (D1) in the second direction that is less than or equal to a dimension (D3) in the second direction of each of the contact plugs (64) in the row (R).

### Clause 9

The semiconductor device according to any one of clauses 1 to 8, where the mesa (54) includes an upper portion (54A) including a portion of the first surface (12A) of the semiconductor layer (12), and the contact plugs (64) are arranged in the first direction at an interval (D5) that is greater than a dimension (D1) in the second direction of the upper portion (54A) of the mesa (54).

### Clause 10

The semiconductor device according to any one of clauses 1 to 9, further comprising an emitter electrode (22) located on the insulating layer (14) and connected to the plurality of contact plugs (64).

### Clause 11

The semiconductor device according to clause 10, where the second electrode (48) is electrically connected to the emitter electrode (22).

### Clause 12

The semiconductor device according to clause 2, where the second region (58A) has a second conductivity type impurity concentration of 1×10¹⁵ cm⁻³ to 1×10¹⁸ cm⁻³, inclusive, and the plurality of in-base regions (66) have a second conductivity type impurity concentration of 1×10¹⁹ cm⁻³ to 1×10²⁰ cm⁻³, inclusive.

### Clause 13

The semiconductor device according to clause 2, where the mesa (54) further includes a plurality of complementary regions (402) of the second conductivity type, the plurality of complementary regions (402) having a second conductivity type impurity concentration that is greater than a second conductivity type impurity concentration of the second region (58A) and less than a second conductivity type impurity concentration of the plurality of in-base regions (66), the plurality of complementary regions (402) each at least partially surrounding one of the plurality of in-base regions (66) in plan view.

### Clause 14

The semiconductor device according to clause 13, where the second region (58A) has a second conductivity type impurity concentration of 1×10¹⁵ cm⁻³ to 1×10¹⁸ cm⁻³, inclusive, the plurality of complementary regions (402) have a second conductivity type impurity concentration of 1×10¹⁸ cm⁻³ to 1×10¹⁹ cm⁻³, inclusive, and the plurality of in-base regions (66) have a second conductivity type impurity concentration of 1×10¹⁹ cm⁻³ to 1×10²⁰ cm⁻³, inclusive.

### Clause 15

The semiconductor device according to clause 2, where:
the first electrode (46) includes a plurality of recesses (804) recessed from an upper surface (46A) of the first electrode (46); and
the plurality of recesses (804) are arranged in the first direction such that each of the plurality of recesses (804) is proximate to a corresponding one of the contact plugs (64) in the row (R).

### Clause 16

The semiconductor device according to clause 15, where each of the plurality of recesses (804) includes a bottom surface (804B) located below the in-base regions (66).

### Clause 17

The semiconductor device according to any one of clauses 1 to 16, further including:
a third trench (42) extending from the first surface (12A) into the semiconductor layer (12); and
a third electrode (46) located in the third trench (42) and separated from the semiconductor layer (12) by the insulating layer (14), where:
the third electrode (46) is electrically connected to the first electrode (46);
the mesa (54) is a first mesa (54);
the third trench (42) extends in the first direction in plan view, the second trench (44) is separated from the third trench (42) in the second direction in plan view, and the semiconductor layer (12) includes a second mesa (54) defined between the second trench (44) and the third trench (42); and
the contact plug row (R) of the contact plugs (202) contacts both the first mesa (54) and the second mesa (54) and is separated from both the first trench (42) and the third trench (42).

### Clause 18

The semiconductor device according to clause 17, where a pitch (D7) of the first trench (42) and the second trench (44) in the second direction is less than a dimension (D6) in the second direction of each of the contact plugs (202) in the row (R).

### Clause 19

The semiconductor device according to any one of clauses 1 to 16, further including:
a third trench (44) extending from the first surface (12A) into the semiconductor layer (12); and
a third electrode (48) located in the third trench (44) and separated from the semiconductor layer (12) by the insulating layer (14), where:
the third electrode (48) is electrically connected to the second electrode (48);
the mesa (54) is a first mesa (54), and the contact plug row (R) is a first contact plug row (R);
the third trench (44) extends in the first direction in plan view, and the semiconductor layer (12) includes a second mesa (54) defined between the first trench (42) and the third trench (44); and
the contact plugs include a second contact plug row (R) in contact with the second mesa (54), the contact plugs in the second contact plug row (R) are spaced apart from one another in the first direction, and the second contact plug row (R) at least partially overlaps the third trench (44) in plan view and is separated from the first trench (42).

### Clause 20

The semiconductor device according to any one of clauses 1 to 16, further including a plurality of trenches (42, 44) extending from the first surface (12A) into the semiconductor layer (12), where:
each of the plurality of trenches (42, 44) extends in the first direction in plan view;
the plurality of trenches (42, 44) include
   a left gate trench (42),
   a right gate trench (42), and
   one or more dummy trenches (44) located between the left gate trench (42) and the right gate trench (42);
the first trench (42) is the left gate trench (42); and
the second trench (44) is, among the one or more dummy trenches (44), a dummy trench (44) located closest to the left gate trench (42).

Exemplary descriptions are given above. In addition to the elements and methods (manufacturing processes) described to illustrate the technology of this disclosure, a person skilled in the art would recognize the potential for a wide variety of combinations and substitutions. All variations within the scope of the claims and their equivalents are included in the disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a semiconductor layer including a first surface;
a first trench and a second trench extending from the first surface into the semiconductor layer;
an insulating layer located on the semiconductor layer;
a first electrode located in the first trench and separated from the semiconductor layer by the insulating layer;
a second electrode located in the second trench and separated from the semiconductor layer by the insulating layer, the second electrode being electrically insulated from the first electrode; and
contact plugs extending through the insulating layer and contacting the semiconductor layer, wherein:
the first trench and the second trench each extend in a first direction in plan view, the first trench is separated from the second trench in a second direction that is orthogonal to the first direction in plan view, and the semiconductor layer includes a mesa defined between the first trench and the second trench; and
the contact plugs include a contact plug row in contact with the mesa, the contact plug row at least partially overlaps the second trench in plan view and is separated from the first trench, and the contact plugs in the row are spaced apart from one another in the first direction.

2. The semiconductor device according to claim 1, wherein:
the mesa includes
a first region of a first conductivity type,
a second region of a second conductivity type located on the first region,
a third region of the first conductivity type located on the second region and including a portion of the first surface of the semiconductor layer, and
a plurality of in-base regions of the second conductivity type, the plurality of in-base regions having a greater second conductivity type impurity concentration than the second region; and
each of the plurality of in-base regions is in contact with a bottom portion of a corresponding one of the contact plugs in the row, and the plurality of in-base regions are spaced apart from one another in the first direction.

3. The semiconductor device according to claim 2, wherein each of the plurality of in-base regions is located between the third region and the first region and extends across an entire width of the mesa in the second direction.

4. The semiconductor device according to claim 2, wherein each of the contact plugs in the row extends through the third region.

5. The semiconductor device according to claim 1, wherein each of the contact plugs in the row is in contact with the second electrode.

6. The semiconductor device according to claim 1, wherein the contact plugs in the row are arranged at constant intervals in the first direction.

7. The semiconductor device according to claim 1, wherein the mesa includes an upper portion including a portion of the first surface of the semiconductor layer, the upper portion of the mesa having a dimension in the second direction that is less than or equal to 0.8 μm.

8. The semiconductor device according to claim 1, wherein the mesa includes an upper portion including a portion of the first surface of the semiconductor layer, the upper portion of the mesa having a dimension in the second direction that is less than or equal to a dimension in the second direction of each of the contact plugs in the row.

9. The semiconductor device according to claim 1, wherein the mesa includes an upper portion including a portion of the first surface of the semiconductor layer, and the contact plugs are arranged in the first direction at an interval that is greater than a dimension in the second direction of the upper portion of the mesa.

10. The semiconductor device according to claim 1, further comprising an emitter electrode located on the insulating layer and connected to the plurality of contact plugs.

11. The semiconductor device according to claim 10, wherein the second electrode is electrically connected to the emitter electrode.

12. The semiconductor device according to claim 2, wherein the second region has a second conductivity type impurity concentration of 1×10¹⁵ cm⁻³ to 1×10¹⁸ cm⁻³, inclusive, and the plurality of in-base regions have a second conductivity type impurity concentration of 1×10¹⁹ cm⁻³ to 1×10²⁰ cm⁻³, inclusive.

13. The semiconductor device according to claim 2, wherein the mesa further includes a plurality of complementary regions of the second conductivity type, the plurality of complementary regions having a second conductivity type impurity concentration that is greater than a second conductivity type impurity concentration of the second region and less than a second conductivity type impurity concentration of the plurality of in-base regions, the plurality of complementary regions each at least partially surrounding one of the plurality of in-base regions in plan view.

14. The semiconductor device according to claim 13, wherein the second region has a second conductivity type impurity concentration of 1×10¹⁵ cm⁻³ to 1×10¹⁸ cm⁻³, inclusive, the plurality of complementary regions have a second conductivity type impurity concentration of 1×10¹⁸ cm⁻³ to 1×10¹⁹ cm⁻³, inclusive, and the plurality of in-base regions have a second conductivity type impurity concentration of 1×10¹⁹ cm⁻³ to 1×10²⁰ cm⁻³, inclusive.

15. The semiconductor device according to claim 2, wherein:
the first electrode includes a plurality of recesses recessed from an upper surface of the first electrode; and
the plurality of recesses are arranged in the first direction such that each of the plurality of recesses is proximate to a corresponding one of the contact plugs in the row.

16. The semiconductor device according to claim 15, wherein each of the plurality of recesses includes a bottom surface located below the in-base regions.

17. The semiconductor device according to claim 1, further comprising:
a third trench extending from the first surface into the semiconductor layer; and
a third electrode located in the third trench and separated from the semiconductor layer by the insulating layer, wherein:
the third electrode is electrically connected to the first electrode;
the mesa is a first mesa;
the third trench extends in the first direction in plan view, the second trench is separated from the third trench in the second direction in plan view, and the semiconductor layer includes a second mesa defined between the second trench and the third trench; and
the contact plug row contacts both the first mesa and the second mesa and is separated from both the first trench and the third trench.

18. The semiconductor device according to claim 17, wherein a pitch of the first trench and the second trench in the second direction is less than a dimension in the second direction of each of the contact plugs in the row.

19. The semiconductor device according to claim 1, further comprising:
a third trench extending from the first surface into the semiconductor layer; and
a third electrode located in the third trench and separated from the semiconductor layer by the insulating layer, wherein:
the third electrode is electrically connected to the second electrode;
the mesa is a first mesa, and the contact plug row is a first contact plug row;
the third trench extends in the first direction in plan view, and the semiconductor layer includes a second mesa defined between the first trench and the third trench; and
the contact plugs include a second contact plug row in contact with the second mesa, the contact plugs in the second contact plug row are spaced apart from one another in the first direction, and the second contact plug row at least partially overlaps the third trench in plan view and is separated from the first trench.

20. The semiconductor device according to claim 1, further comprising:
a plurality of trenches extending from the first surface into the semiconductor layer, wherein:
each of the plurality of trenches extends in the first direction in plan view;
the plurality of trenches include
a left gate trench,
a right gate trench, and
one or more dummy trenches located between the left gate trench and the right gate trench;
the first trench is the left gate trench; and
the second trench is, among the one or more dummy trenches, a dummy trench located closest to the left gate trench.
